(19) United States
(12) Patent Application Publication
(10) Pub. No.: US 2026/0107595 A1
(43) Pub. Date: Apr. 16, 2026

(54) IMAGE SENSOR

(71) Applicant: SAMSUNG ELECTRONICS CO., LTD., Suwon-si (KR)

(72) Inventors: Hyunkyu Choi, Suwon-si (KR); Jongsu Yoon, Suwon-si (KR); Taesung Lee, Suwon-si (KR)

(73) Assignee: SAMSUNG ELECTRONICS CO., LTD., Suwon-si (KR)

(21) Appl. No.: 19/225,354

(22) Filed: Jun. 2, 2025

(30) Foreign Application Priority Data
Oct. 11, 2024 (KR) 10-2024-0138750

(51) Int. Cl. H10F 39/00

(52) U.S. Cl. CPC H10F 39/8063; H10F 39/024

(57) ABSTRACT

An image sensor includes: a first active region including a first photoelectric conversion region; a second active region including a second photoelectric conversion region, wherein the second active region has a smaller area than the first active region; a plurality of first lenses on the first active region; and a second lens on the second active region, wherein the second lens is connected to one of the plurality of first lenses and spaced apart from the other first lenses.

### CROSS-REFERENCE TO RELATED APPLICATIONS

The application is based on and claims priority under 35 U.S.C. § 119 to Korean Patent Application No. 10-2024-0138750, filed on October 11, 2024, in the Korean Intellectual Property Office, the disclosure of which is incorporated by reference herein in its entirety.

### BACKGROUND

The present disclosure relates to an image sensor and a method for manufacturing the image sensor.

An image sensor converts an optical image signal into an electrical signal. Image sensors are classified into charge-coupled device (CCD) image sensors and complementary metal-oxide semiconductor (CMOS) image sensors. An image sensor contains multiple pixels. Each pixel may include a photoelectric conversion region that receives incident light and converts it into an electrical signal, and a pixel circuit that uses the charge generated in the photoelectric conversion region to output a pixel signal. Image sensors may be utilized in various fields such as digital cameras, camcorders, smartphones, game devices, security cameras, medical micro cameras, robots, and vehicles.

### SUMMARY

Provided is an image sensor having improved optical characteristics and improved manufacturing process efficiency.

Provided is a method for manufacturing an image sensor having improved optical characteristics and improved manufacturing process efficiency.

According to an aspect of the disclosure, an image sensor includes: a first active region including a first photoelectric conversion region; a second active region including a second photoelectric conversion region, wherein the second active region has a smaller area than the first active region; a plurality of first lenses on the first active region; and a second lens on the second active region, wherein the second lens is connected to one of the plurality of first lenses and spaced apart from the other first lenses.

According to an aspect of the disclosure, an image sensor includes: first active regions arranged in a 2×2 form along a first direction and a second direction, wherein each of the first active regions includes first photoelectric conversion regions; a second active region provided between the first active regions, wherein the second active region includes a second photoelectric conversion region and the second active region has a smaller area than each of the first active regions; a first lens group, a second lens group, a third lens group, and a fourth lens group that are provided on respective first active regions and, wherein each of the first lens group, the second lens group, the third lens group, and the fourth lens group includes a plurality of first lenses; and a second lens provided between the first lens group, the second lens group, the third lens group, and the fourth lens group, wherein the second lens is connected to one of the plurality of first lenses in each of the first lens group, the second lens group, the third lens group, and the fourth lens group, and wherein the second lens is spaced apart from the other first lenses.

According to an aspect of the disclosure, an image sensor includes: a first active region comprising a first photoelectric conversion region; a plurality of second active regions arranged along an edge of the fist active region, wherein each of the plurality of second active regions comprises a plurality of second photoelectric conversion regions; a plurality of first lenses on the first active region; a plurality of second lenses on the plurality of second active regions, respectively; wherein the plurality of second lenses are connected to one of the plurality of first lenses, and wherein the plurality of second lenses are spaced apart from the other first lenses.

Additional aspects will be set forth in part in the description which follows and, in part, will be apparent from the description, or may be learned by practice of the presented embodiments.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 is a block diagram of an image sensor according to an example embodiment;

FIG. 2 is a plan view of a pixel array of FIG. 1;

FIG. 3 is an equivalent circuit diagram of a pixel group of FIG. 1;

FIG. 4 is a plan view of an image sensor according to example embodiments;

FIG. 5 is a plan view showing first active regions and second active regions of FIG. 4;

FIG. 6 is a plan view of a lens layer of FIG. 4;

FIG. 7 is a cross-sectional view taken along line A1-A1’ of FIG. 4;

FIG. 8 is a cross-sectional view taken along line A2-A2’ of FIG. 4;

FIGS. 9 to 12 are cross-sectional views corresponding to FIG. 7 that illustrates a method of manufacturing the lens layer of the image sensor described with reference to FIGS. 4 to 8;

FIG. 13 is a plan view of an image sensor according to example embodiments;

FIG. 14 is a plan view of the lens layer of FIG. 13;

FIG. 15 is a plan view of an image sensor according to example embodiments;

FIG. 16 is a plan view of the lens layer of FIG. 15;

FIG. 17 is a plan view of an image sensor according to example embodiments;

FIG. 18 is a plan view of the lens layer of FIG. 17;

FIG. 19 is a plan view of an image sensor according to example embodiments;

FIG. 20 is a plan view of the lens layer of FIG. 19;

FIG. 21 is a plan view of an image sensor according to example embodiments;

FIG. 22 is a plan view of the lens layer of FIG. 21;

FIG. 23 is a plan view of an image sensor according to example embodiments; and

FIG. 24 is a plan view of the lens layer of FIG. 23.

### DETAILED DESCRIPTION

Hereinafter, example embodiments are described in detail with reference to the accompanying drawings. Same or similar components are denoted by the same or similar reference numerals throughout the specification, and repeated descriptions of the same or similar components are omitted. When an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Embodiments described herein are example embodiments. The present disclosure is not limited to some embodiments described in the present disclosure. Other embodiments may be realized in various other forms. Each example embodiment provided in the following description is not excluded from being associated with one or more features of another example or another example embodiment also provided herein or not provided herein but consistent with the present disclosure. Even if a certain step or operation of manufacturing an apparatus or structure is described later than another step or operation, the step or operation may be performed later than the other step or operation unless the other step or operation is described as being performed after the step or operation.

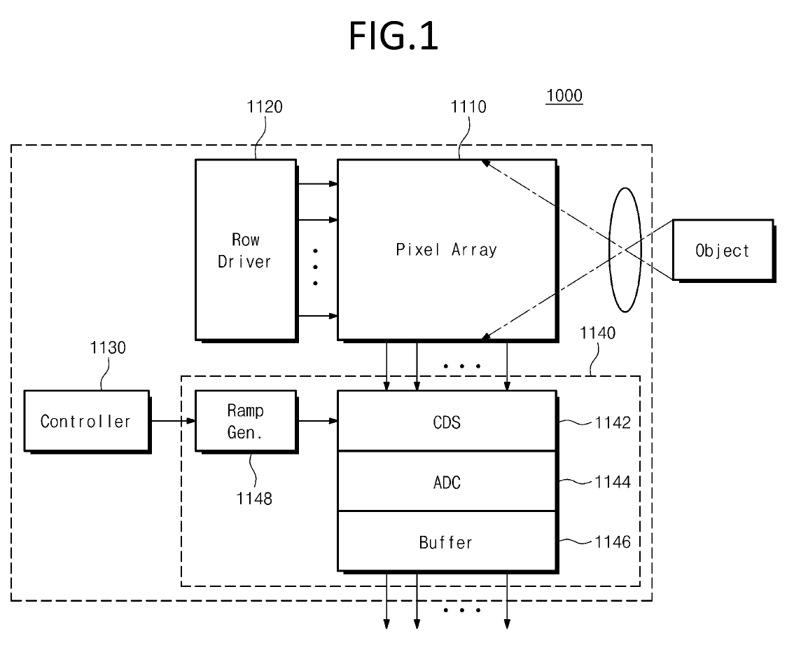

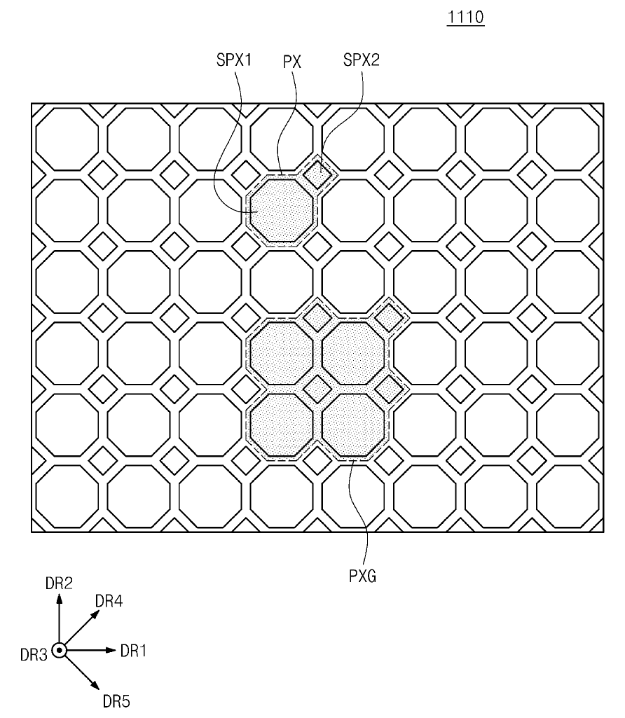

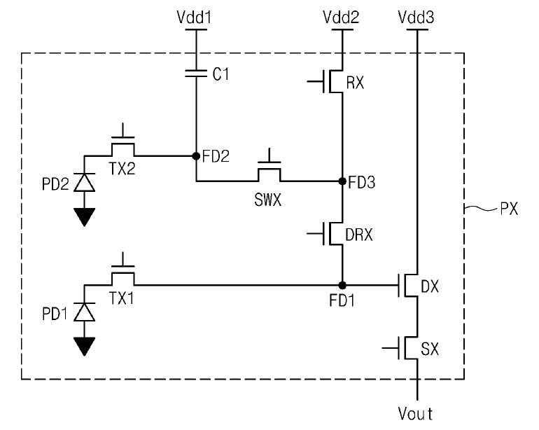

FIG. 1 is a block diagram of an image sensor according to an example embodiment. FIG. 2 is a plan view of a pixel array of FIG. 1. FIG. 3 is an equivalent circuit diagram of a pixel group of FIG. 1.

Referring to FIG. 1, an image sensor 1000 may be provided. The image sensor 1000 may be mounted in electronic devices having image or light sensing functions. For example, the image sensor 1000 may be mounted in electronic devices such as cameras, smartphones, wearable devices, Internet of Things (IoT) devices, tablet Personal Computers (PCs), Personal Digital Assistants (PDAs), Portable Multimedia Players (PMPs), navigation devices, and the like. The image sensor 1000 may be mounted in electronic devices that are provided as components in vehicles, furniture, manufacturing equipment, doors, various measuring instruments, and the like.

In an embodiment, the image sensor 1000 may include a pixel array 1110, a row driver 1120, a controller 1130, and a pixel signal processor 1140.

Referring to FIGS. 2 and 3, the pixel array 1110 may include a plurality of pixels PX arranged two-dimensionally along a first direction DR1 and a second direction DR2. The plurality of pixels PX may be arranged in a regular pattern to generate high-quality images. For example, the plurality of pixels PX may be arranged in a Bayer pattern or a chess mosaic pattern. For example, each of the plurality of pixels PX may receive red light, green light, or blue light.

Each of the plurality of pixels PX may include a first sub-pixel region SPX1 and a second sub-pixel region SPX2. The first sub-pixel region SPX1 and the second sub-pixel region SPX2 may include a first photoelectric conversion device PD1 and a second photoelectric conversion device PD2, respectively. The first photoelectric conversion device PD1 and the second photoelectric conversion device PD2 may absorb light to generate charge carriers (electrons or holes). For example, the first photoelectric conversion device PD1 and the second photoelectric conversion device PD2 may include photodiodes, phototransistors, photogates, or pinned photodiodes. The first photoelectric conversion device PD1 and the second photoelectric conversion device PD2 may have different sensitivities. For example, the first photoelectric conversion device PD1 may have higher sensitivity than the second photoelectric conversion device PD2. The output voltage of the plurality of pixels PX may be determined based on charge carriers generated by the first photoelectric conversion device PD1 and the second photoelectric conversion device PD2. The first photoelectric conversion device PD1 will be described in detail later with respect to the second photoelectric conversion device PD2.

The first sub-pixel region SPX1 and the second sub-pixel region SPX2 in the same pixel PX may receive substantially the same color of light. The first sub-pixel region SPX1 and the second sub-pixel region SPX2 in the same pixel PX may be arranged along a fourth direction DR4 that intersects with the first direction DR1 and the second direction DR2, as shown in FIG. 2. The first sub-pixel region SPX1 may have a larger area than the second sub-pixel region SPX2. For example, the first sub-pixel region SPX1 may have an octagonal shape. In other example embodiments, the first sub-pixel region SPX1 may have a shape different from the octagonal shape. For example, the second sub-pixel region SPX2 may have a rectangular shape. In other example embodiments, the second sub-pixel region SPX2 may have a shape different from the rectangular shape.

The plurality of pixels PX may be classified into a plurality of pixel groups PXG. The plurality of pixel groups PXG may be arranged two-dimensionally. For example, each of the plurality of pixel groups PXG may include a red pixel, a green pixel, another green pixel, and a blue pixel arranged in a 2 x 2 configuration. In an embodiment, the pixel group PXG includes four (4) pixels PX. In other embodiments, the pixel group PXG may include fewer or more than four (4) pixels PX.

The pixel array 1110 may be driven by receiving multiple driving signals from the row driver 1120, including row selection signals, reset signals, charge transfer signals, gain control signals, and switch signals. The row driver 1120 may provide multiple driving signals to the pixel array 1110 for driving the multiple pixels. In one example, the driving signals may be provided on a row-by-row basis to the pixel array 1110. The pixels belonging to one row of the pixel array 1110 selected by the driving signals of the row driver 1120 may be simultaneously activated by signals output from the row driver 1120. The selected row’s pixels may provide output voltages corresponding to absorbed light to corresponding column output lines. In one example, the pixels may provide output voltages one row at a time. The output voltages may be provided to a correlated double sampler (CDS) 1142.

The pixel signal processor 1140 may include the correlated double sampler 1142, an analog-to-digital converter (ADC) 1144, and a buffer 1146. The correlated double sampler 1142 may sample and hold the output voltages provided by the pixel array 1110. The correlated double sampler 1142 may reduce noise and improve the Signal-to-Noise Ratio (SNR). The correlated double sampler 1142 may be configured to remove noise voltage from the pixel output voltage. For example, the correlated double sampler 1142 may perform double sampling of a particular noise level and a signal level due to the output signal, and output a difference level corresponding to the difference between the noise level and signal level. The correlated double sampler 1142 may receive a ramp signal generated by a ramp signal generator 1148, compare them, and output the comparison result.

The analog-to-digital converter 1144 may convert an analog signal corresponding to the difference level received from the correlated double sampler 1142 into a digital signal. The buffer 1146 may latch the digital signal, and the latched signal may be sequentially output to outside the image sensor 1100 to be transmitted to an image processor.

The controller 1130 may control the row driver 1120 to cause the pixel array 1110 to absorb light and accumulate charge carriers, temporarily store the accumulated charges, and output electrical signals corresponding to the stored charges to outside the pixel array 1110. The controller 1130 may control the pixel signal processor 1140 to measure output voltages provided by the pixel array 1110.

The pixel PX may include a first photoelectric conversion device PD1, a second photoelectric conversion device PD2, a first transfer transistor TX1, a second transfer transistor TX2, a reset transistor RX, a source follower transistor DX, a selection transistor SX, a conversion gain transistor DRX, a switch transistor SWX, a first floating diffusion region FD1, a second floating diffusion region FD2, a third floating diffusion region FD3, and a capacitor C1.

The first photoelectric conversion device PD1 and the second photoelectric conversion device PD2 may be configured to generate charge carriers corresponding to the intensity of incident light. The charge carriers may be electrons or holes. The first photoelectric conversion device PD1 and the second photoelectric conversion device PD2 may have different sensitivities. For example, the sensitivity of the first photoelectric conversion device PD1 may be higher than that of the second photoelectric conversion device PD2.

The first transfer transistor TX1 may be provided between the first photoelectric conversion device PD1 and the first floating diffusion region FD1. The first transfer transistor TX1 may be configured to control electrical connection between the first photoelectric conversion device PD1 and the first floating diffusion region FD1. For example, the first transfer transistor TX1 may be configured to transfer charge carriers generated in the first photoelectric conversion device PD1 to the first floating diffusion region FD1 in response to a first transfer control signal input to its gate terminal.

The first floating diffusion region FD1 may receive and accumulate charges transferred from the first photoelectric conversion device PD1. The source follower transistor DX may be controlled according to the amount of charge accumulated in the first floating diffusion region FD1.

The second transfer transistor TX2 may be provided between the second photoelectric conversion device PD2 and the second floating diffusion region FD2. The second transfer transistor TX2 may be configured to control electrical connection between the second photoelectric conversion device PD2 and the second floating diffusion region FD2. The second transfer transistor TX2 may include a second transfer gate TG1. For example, the second transfer transistor TX2 may be configured to transfer charge carriers generated in the second photoelectric conversion device PD2 to the second floating diffusion region FD2 in response to a second transfer control signal input to its gate terminal.

A first electrode of the capacitor C1 may be electrically connected to the second floating diffusion region FD2. The voltage of the second floating diffusion region FD2 may be applied to the first electrode of the capacitor C1. A second electrode of the capacitor C1 may be configured to receive a first voltage Vdd1. For example, the capacitor C1 may be configured to accumulate charge carriers that overflow from the second photoelectric conversion device PD2 after being generated by the second photoelectric conversion device PD2.

The switch transistor SWX may be provided between the second floating diffusion region FD2 and the third floating diffusion region FD3. The switch transistor SWX may be configured to control electrical connection between the second floating diffusion region FD2 and the third floating diffusion region FD3. For example, the switch transistor SWX may electrically connect the second floating diffusion region FD2 and the third floating diffusion region FD3 in response to a switch control signal input to its gate terminal.

The conversion gain transistor DRX may be provided between the first floating diffusion region FD1 and the third floating diffusion region FD3. The conversion gain transistor DRX may be configured to control electrical connection between the first floating diffusion region FD1 and the third floating diffusion region FD3 and control the conversion gain. The conversion gain refers to the ratio at which charge accumulated in the floating diffusion region electrically connected to the gate terminal of the source follower transistor DX is converted to voltage, and the conversion gain decreases as capacitance increases. The conversion gain transistor DRX may be configured to turn on or off according to a conversion gain signal input to the gate terminal of the conversion gain transistor DRX.

When the conversion gain transistor DRX is turned on, the first floating diffusion region FD1 and the third floating diffusion region FD3 may be electrically connected, and the floating diffusion region (i.e., the first floating diffusion region FD1 and the third floating diffusion region FD3) electrically connected to the gate terminal of the source follower transistor DX may have relatively large capacitance. The image sensor 1000 may have relatively small conversion gain.

When the conversion gain transistor DRX is turned off, the first floating diffusion region FD1 and the third floating diffusion region FD3 may be electrically isolated from each other, and the floating diffusion region (i.e., the first floating diffusion region FD1) electrically connected to the gate terminal of the source follower transistor DX may have relatively small capacitance. The image sensor 1000 may have relatively large conversion gain.

The reset transistor RX may be configured to periodically reset the first to third floating diffusion regions FD1, FD2, FD3 by a reset signal applied to its gate terminal. A first source/drain terminal of the reset transistor RX may be connected to the third floating diffusion region FD3. A second voltage Vdd2 may be applied to a second source/drain terminal of the reset transistor RX. In example embodiments, when the reset transistor RX is turned on, at least one of the switch transistor SWX and the conversion gain transistor DRX may be turned on together. Accordingly, charges accumulated in at least one of the corresponding first to third floating diffusion regions FD1, FD2, FD3 may be reset.

The gate terminal of the source follower transistor DX may be electrically connected to the first floating diffusion region FD1. A third voltage Vdd3 may be applied to the second source/drain terminal of the source follower transistor DX. The first source/drain terminal of the source follower transistor DX may be electrically connected to the second source/drain terminal of the selection transistor SX. The source follower transistor DX may be a source follower buffer amplifier that outputs current proportional to the amount of charge in the floating diffusion region electrically connected to its gate terminal. The source follower transistor DX may output a voltage corresponding to the amount of charge accumulated in the floating diffusion region electrically connected to its gate terminal.

The second source/drain terminal of the selection transistor SX may be electrically connected to the first source/drain terminal of the source follower transistor DX. An output voltage Vout may be output from the first source/drain terminal of the selection transistor SX.

Charge carriers generated by the first photoelectric conversion device PD1 may be read out in either a high conversion gain (HCG) mode or a low conversion gain (LCG) mode according to the gain control signal. In the HCG mode, the gain control signal may have an inactive level, and the conversion gain transistor DRX may be turned off. Accordingly, the first floating diffusion region FD1 and the third floating diffusion region FD3 may not be electrically connected. In the LCG mode, the gain control signal (CGS) may have an active level, and the conversion gain transistor DRX may be turned on. Accordingly, the first floating diffusion region FD1 and the third floating diffusion region FD3 may be electrically connected.

Charge carriers generated by the second photoelectric conversion device PD2 may be read out in either a first mode for reading charge carriers accumulated in the second photoelectric conversion device PD2 or a second mode for reading charge carriers that have overflowed from the second photoelectric conversion device PD2 and are stored in the capacitor C1.

The first photoelectric conversion device PD1 may generate a first pixel signal corresponding to a lowest first illuminance range in the high conversion gain (HCG) mode, and generate a second pixel signal corresponding to a second illuminance range higher than the first illuminance range in the low conversion gain (LCG) mode. The second photoelectric conversion device PD2 may generate a third pixel signal corresponding to a third illuminance range higher than the second illuminance range in the first mode, and generate a fourth pixel signal corresponding to a highest fourth illuminance range in the second mode. The first to fourth pixel signals may be synthesized into one image, and the synthesized image may have a high dynamic range. Furthermore, LED flicker mitigation (LFM) may be achieved when increasing the exposure time of the second photoelectric conversion device PD2.

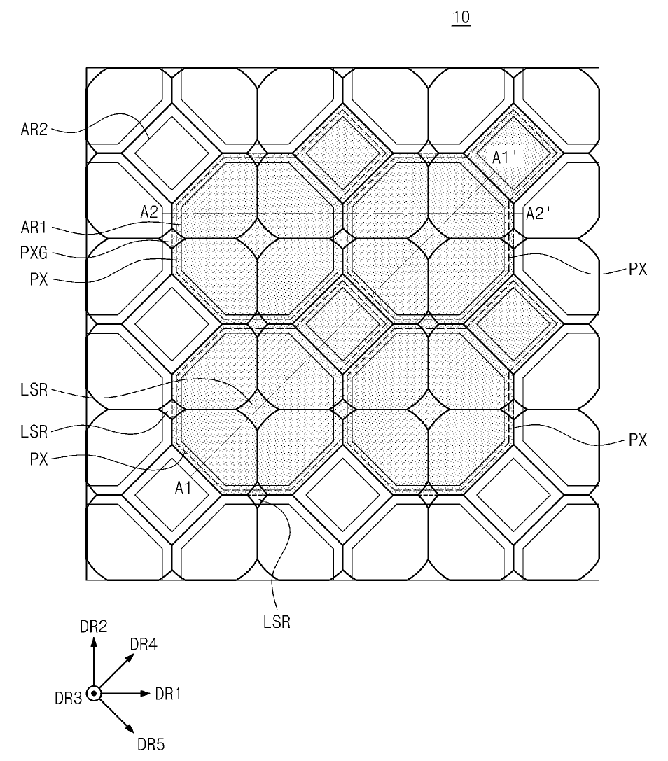

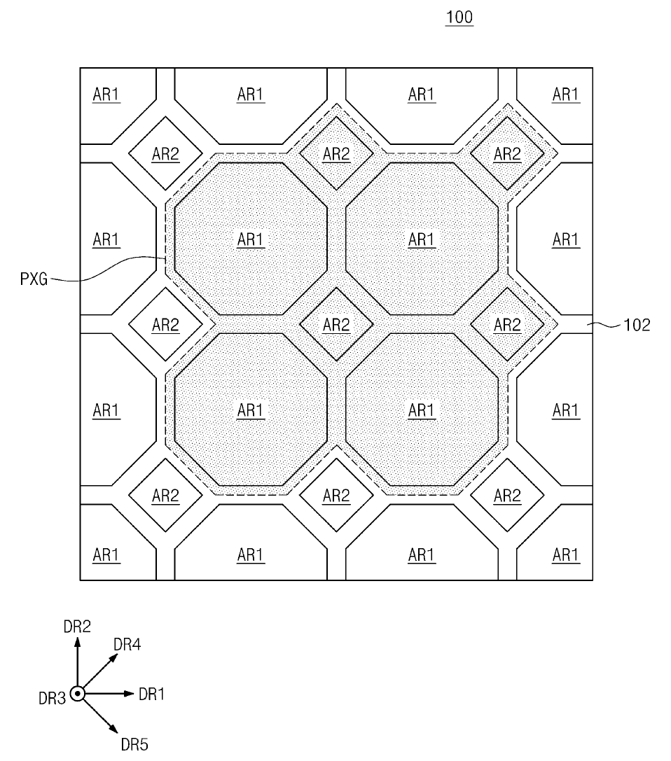

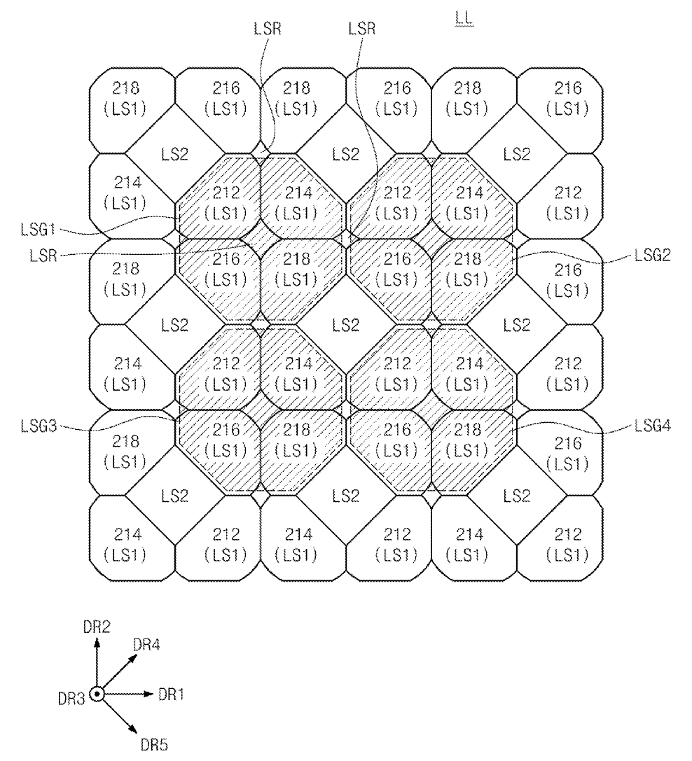

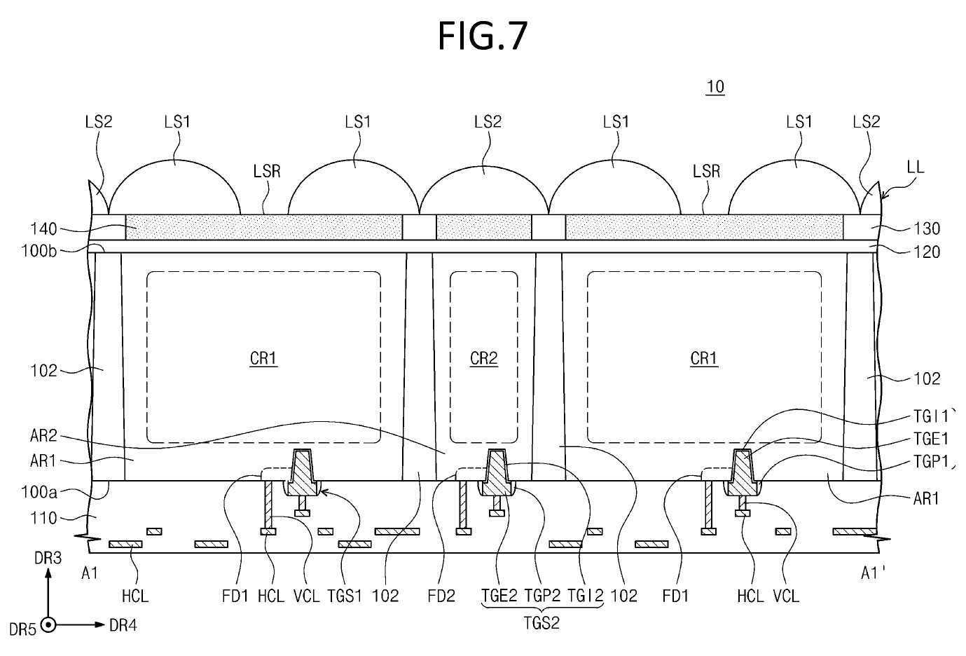

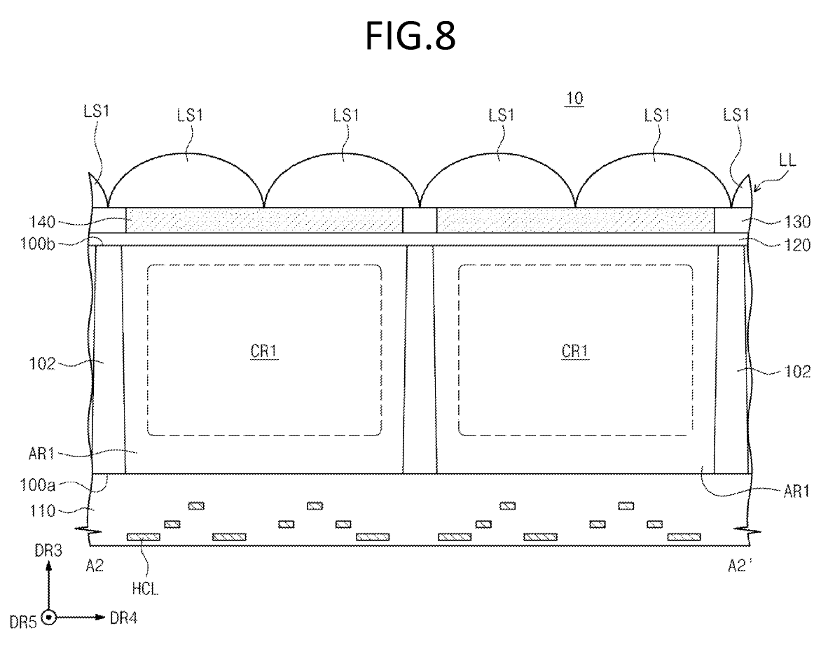

FIG. 4 is a plan view of an image sensor according to example embodiments. FIG. 5 is a plan view showing first active regions and second active regions of FIG. 4. FIG. 6 is a plan view of a lens layer of FIG. 4. FIG. 7 is a cross-sectional view taken along line A1-A1’ of FIG. 4. FIG. 8 is a cross-sectional view taken along line A2-A2’ of FIG. 4.

FIGS. 4 to 8 illustrate a pixel group PXG (of FIG. 2). The pixel group PXG may include 4 pixels PX arranged in a 2 x 2 configuration along the first direction DR1 and the second direction DR2.

FIGS. 4 to 8 illustrates a substrate 100. The substrate 100 may include a first surface 100a and a second surface 100b positioned opposite to each other. The first surface 100a and the second surface 100b may extend along the first direction DR1 and the second direction DR2. The first surface 100a and the second surface 100b may be spaced apart along a third direction DR3. For example, the first to third directions DR1 to DR3 may be perpendicular to each other.

The substrate 100 may be a semiconductor substrate. For example, the substrate 100 may include silicon (Si), germanium (Ge), or silicon-germanium (SiGe). The substrate 100 may have a first conductivity type. For example, the first conductivity type may be p-type or n-type. When the substrate 100 is p-type, the substrate 100 may include group III elements (for example, boron (B), aluminum (Al), gallium (Ga), indium (In), etc.) or group II elements as impurities. Hereinafter, regions having p-type conductivity may include group III or group II elements as impurities. When the substrate 100 is n-type, the substrate 100 may include group V elements (for example, phosphorus (P), arsenic (As), antimony (Sb), etc.), group VI, or group VII elements as impurities. Hereinafter, regions having n-type conductivity may include group V, group VI, or group VII elements as impurities. Hereinafter, impurities that make the substrate 100 have the first conductivity type and the second conductivity type may be referred to as first impurities and second impurities, respectively. When the first conductivity type is p-type or n-type, the second conductivity type may be n-type or p-type, respectively. The substrate 100 may be an epitaxial layer formed by an epitaxial growth process.

The substrate 100 may include first active regions AR1 and second active regions AR2 defined by an isolation layer 102. One second active region AR2 may be surrounded by four first active regions AR1. The four first active regions AR1 may be arranged in a 2 x 2 configuration along the first direction DR1 and the second direction DR2. The first active region AR1 may have a larger area than the second active region AR2. For example, the first active region AR1 may have an octagonal shape. In other example embodiments, the first active region AR1 may have a shape different from the octagonal shape. For example, the second active region AR2 may have a rectangular shape. In other example embodiments, the second active region AR2 may have a shape different from the rectangular shape.

First photoelectric conversion regions CR1 and second photoelectric conversion regions CR2 may be provided within the first active regions AR1 and the second active regions AR2, respectively. From a planar view, the first photoelectric conversion region CR1 may have a larger area than the second photoelectric conversion region CR2. In example embodiments, each of the first photoelectric conversion region CR1 and the second photoelectric conversion region CR2 may include at least one photodiode. For example, each of the first photoelectric conversion region CR1 and the second photoelectric conversion region CR2 may include a pn photodiode. When the substrate 100 is p-type, the p-type region of the first photoelectric conversion region CR1 and the second photoelectric conversion region CR2 may be the substrate 100, and the n-type region may be formed by implanting second impurities into the substrate 100. In example embodiments, the first photoelectric conversion region CR1 and the second photoelectric conversion region CR2 may include multiple pn junctions located at different depths.

When light is incident on the first photoelectric conversion region CR1 and the second photoelectric conversion region CR2, electron-hole pairs (EHPs) may be generated in the first photoelectric conversion region CR1 and the second photoelectric conversion region CR2. For example, electron-hole pairs may be generated in a depletion region formed adjacent to the pn junction. More electron-hole pairs may be generated as the intensity of light incident on the first photoelectric conversion region CR1 and the second photoelectric conversion region CR2 becomes stronger. In example embodiments, a reverse bias may be applied to the first photoelectric conversion region CR1 and the second photoelectric conversion region CR2 to accumulate charge carriers (electrons or holes).

First floating diffusion regions FD1 and second floating diffusion regions FD2 may be provided in the first active regions AR1 and the second active regions AR2, respectively. For example, the first floating diffusion regions FD1 and the second floating diffusion regions FD2 may be formed in portions adjacent to the first surface 100a of the first active regions AR1 and the second active regions AR2, respectively. The first floating diffusion regions FD1 and the second floating diffusion regions FD2 may have the second conductivity type. In example embodiments, the first floating diffusion regions FD1 and the second floating diffusion regions FD2 may be formed by implanting second impurities into the substrate 100. The first floating diffusion regions FD1 and the second floating diffusion regions FD2 may be spaced apart from the first photoelectric conversion region CR1 and the second photoelectric conversion region CR2, respectively. The regions between the first floating diffusion region FD1 and first photoelectric conversion region CR1 and between the second floating diffusion region FD2 and the second photoelectric conversion region CR2 may have the first conductivity type.

First transfer gate structures TGS1 and second transfer gate structures TGS2 may be provided in the first active regions AR1 and the second active regions AR2, respectively. The first transfer gate structures TGS1 and the second transfer gate structures TGS2 may be referred to as Vertical Transfer Gates (VTG). The first transfer gate structure TGS1 may include a first transfer gate electrode TGE1, a first transfer gate insulating film TGI1, and first transfer gate spacers TGP1. The second transfer gate structure TGS2 may include a second transfer gate electrode TGE2, a second transfer gate insulating film TGI2, and second transfer gate spacers TGP2.

The first transfer gate electrode TGE1 may be adjacent to the first floating diffusion region FD1 and the first photoelectric conversion region CR1. The second transfer gate electrode TGE2 may be adjacent to the second floating diffusion region FD2 and the second photoelectric conversion region CR2. Each of the first transfer gate electrode TGE1 and the second transfer gate electrode TGE2 may include a protruding portion provided on the first surface 100a and an insertion portion inserted into the substrate 100. For example, each of the first transfer gate electrode TGE1 and the second transfer gate electrode TGE2 may include one insertion portion. In other example embodiments, each of the first transfer gate electrode TGE1 and the second transfer gate electrode TGE2 may include two or more insertion portions connected to one protruding portion. The first transfer gate electrode TGE1 and the second transfer gate electrode TGE2 may include electrically conductive material. For example, the first transfer gate electrode TGE1 and the second transfer gate electrode TGE2 may include doped polysilicon or metal (for example, copper (Cu), aluminum (Al), molybdenum (Mo), platinum (Pt), titanium (Ti), tantalum (Ta), tungsten (W), or combinations thereof).

The first transfer gate insulating film TGI1 may be provided between the first transfer gate electrode TGE1 and the first active region AR1. The first transfer gate insulating film TGI1 may be configured to electrically isolate the first transfer gate electrode TGE1 from the substrate 100. The second transfer gate insulating film TGI2 may be provided between the second transfer gate electrode TGE2 and the second active region AR2. The second transfer gate insulating film TGI2 may be configured to electrically isolate the second transfer gate electrode TGE2 from the substrate 100. The first transfer gate insulating film TGI1 and the second transfer gate insulating film TGI2 may extend along the surface of the substrate 100. For example, the first transfer gate insulating film TGI1 and the second transfer gate insulating film TGI2 may include silicon-based insulating material (for example, silicon nitride, silicon oxide, and/or silicon oxynitride) or high-k material (for example, metal oxide containing at least one metal selected from a group consisting of hafnium (Hf), zirconium (Zr), aluminum (Al), tantalum (Ta), titanium (Ti), yttrium (Y) and lanthanide (La)).

The first transfer gate spacers TGP1 and second transfer gate spacers TGP2 may be provided on sidewalls of the first transfer gate electrode TGE1 and the second transfer gate electrode TGE2, respectively. The first transfer gate spacers TGP1 and the second transfer gate spacers TGP2 may include insulating material. For example, the first transfer gate spacers TGP1 and the second transfer gate spacers TGP2 may include silicon-based insulating material (for example, silicon nitride, silicon oxide, and/or silicon oxynitride) or high-k material (for example, metal oxide containing at least one metal selected from a group consisting of hafnium (Hf), zirconium (Zr), aluminum (Al), tantalum (Ta), titanium (Ti), yttrium (Y) and lanthanide (La)).

The first transfer gate structure TGS1, the first photoelectric conversion region CR1, and the first floating diffusion region FD1 may be included in the first transfer transistor TX1 (of FIG. 3). The first transfer gate structure TGS1, the first photoelectric conversion region CR1, and the first floating diffusion region FD1 may be the gate, first source/drain, and second source/drain of the first transfer transistor, respectively. When a voltage that turns on the first transfer transistor TX1 (of FIG. 3) is applied to the first transfer gate electrode TGE1, a channel of the second conductivity type may be formed in a region of the first active region AR1 adjacent to the first transfer gate structure TGS1. The channel may be configured to move charge carriers generated in the first photoelectric conversion region CR1 to the first floating diffusion region FD1. When a voltage that turns on the first transfer transistor TX1 (of FIG. 3) is not applied to the first transfer gate electrode TGE1, charge carriers generated in the first photoelectric conversion region CR1 may be accumulated within the first photoelectric conversion region CR1.

The second transfer gate structure TGS2, the second photoelectric conversion region CR2, and the second floating diffusion region FD2 may become the second transfer transistor TX2 (of FIG. 3). The second transfer gate structure TGS2, the second photoelectric conversion region CR2, and the second floating diffusion region FD2 may be included in the gate, first source/drain, and second source/drain of the second transfer transistor, respectively. When a voltage that turns on the second transfer transistor TX2 (of FIG. 3) is applied to the second transfer gate electrode TGE2, a channel of the second conductivity type may be formed in a region of the second active region AR2 adjacent to the second transfer gate structure TGS2. The channel may be configured to move charge carriers generated in the second photoelectric conversion region CR2 to the second floating diffusion region FD2. When a voltage that turns on the second transfer transistor TX2 (of FIG. 3) is not applied to the second transfer gate electrode TGE2, charge carriers generated in the second photoelectric conversion region CR2 may be accumulated within the second photoelectric conversion region CR2.

The isolation layer 102 may surround each of the first photoelectric conversion region CR1 and the second photoelectric conversion region CR2. The isolation layer 102 may extend along the third direction DR3. In example embodiments, the isolation layer 102 may penetrate through the substrate 100. In example embodiments, the isolation layer 102 may extend from the first surface 100a to a certain depth between the first surface 100a and the second surface 100b. The isolation layer 102 may be configured to prevent or reduce electrical crosstalk phenomenon that degrades the signal-to-noise ratio due to charge carrier exchange between adjacent pixels. For example, the isolation layer 102 may include conductive material (for example, at least one of doped polysilicon, metal, metal silicide, metal nitride, or metal-containing material), insulating material (for example, silicon-based insulating material such as silicon nitride, silicon oxide, and/or silicon oxynitride), or high-k material (for example, metal oxide containing at least one metal selected from a group consisting of hafnium (Hf), zirconium (Zr), aluminum (Al), tantalum (Ta), titanium (Ti), yttrium (Y) and lanthanide (La)).

In example embodiments, the sidewalls of the isolation layer 102 may be doped with a material having high reflectivity to prevent or reduce optical crosstalk phenomenon where light is detected in pixels adjacent to the pixel where the light is incident. For example, the material having high reflectivity may be boron (Boron). When the isolation layer 102 includes conductive material, for example, a negative fixed charge layer may be provided between the isolation layer 102 and the substrate 100. The negative fixed charge layer may include, for example, metal oxide containing at least one metal selected from a group consisting of hafnium (Hf), zirconium (Zr), aluminum (Al), tantalum (Ta), titanium (Ti), yttrium (Y) and lanthanide (La).

In example embodiments, a shallow trench isolation (STI) may be further provided between the isolation layer 102 and the first surface 100a. The shallow trench isolation may be configured to provide electrical isolation between adjacent devices. In example embodiments, the shallow trench isolation may protrude from the sides of the isolation layer 102. In example embodiments, the shallow trench isolation may have substantially the same width as the isolation layer 102. The shallow trench isolation may include electrically insulating material. For example, the shallow trench isolation may include silicon nitride, silicon oxide, silicon oxynitride, or combinations thereof.

In example embodiments, a reset transistor RX (of FIG. 3), a source follower transistor DX (of FIG. 3), a selection transistor SX (of FIG. 3), a conversion gain transistor DRX (of FIG. 3), and a switch transistor SWX (of FIG. 3) may be provided on the first surface 100a of the first active region AR1.

Vertical conductive lines VCL and horizontal conductive lines HCL may be provided on the substrate 100. The vertical conductive lines VCL may extend along the third direction DR3. The horizontal conductive lines HCL may, for example, extend along the first direction DR1 or second direction DR2. The vertical conductive lines VCL and horizontal conductive lines HCL may include electrically conductive material. For example, the vertical conductive lines VCL and horizontal conductive lines HCL may include doped polysilicon or metal (for example, copper (Cu), aluminum (Al), molybdenum (Mo), platinum (Pt), titanium (Ti), tantalum (Ta), tungsten (W), or combinations thereof).

The vertical conductive lines VCL and horizontal conductive lines HCL may provide electrical connections between various components. For example, the vertical conductive lines VCL and horizontal conductive lines HCL may be configured to electrically connect the first floating diffusion region FD1, the gate of the source follower transistor DX (of FIG. 3), and the first source/drain of the conversion gain transistor. For example, the vertical conductive lines VCL and horizontal conductive lines HCL may be configured to electrically connect the second floating diffusion region FD2, the second source/drain of the switch transistor SWX (of FIG. 3), and the first electrode of the capacitor C1. For example, the vertical conductive lines VCL and horizontal conductive lines HCL may be configured to electrically connect the first source/drain of the source follower transistor DX (of FIG. 3) and the second source/drain of the selection transistor SX (of FIG. 3). For example, the vertical conductive lines VCL and horizontal conductive lines HCL may be configured to electrically connect the third floating diffusion region FD3 (of FIG. 3), the first source/drain of the switch transistor SWX (of FIG. 3), the first source/drain of the reset transistor RX (of FIG. 3), and the second source/drain of the conversion gain transistor DRX (of FIG. 3).

An insulating layer 110 may be provided on the first surface 100a. The insulating layer 110 may be configured to protect the vertical conductive lines VCL, horizontal conductive lines HCL, and components provided on the first surface 100a. The insulating layer 110 may include, for example, silicon oxide, silicon nitride, or silicon oxynitride.

An anti-reflection layer 120 may be provided on the second surface 100b. The anti-reflection layer 120 may be configured to reduce or prevent reflection of incident light. The anti-reflection layer 120 may extend along the first direction DR1 and the second direction DR2. For example, the anti-reflection layer 120 may include hafnium oxide (HfO2), silicon oxide (SiO2), silicon nitride (SiN), aluminum oxide (Al2O3), zirconium oxide (ZrO2), tantalum oxide (Ta2O5), titanium oxide (TiO2), lanthanum oxide (La2O3), praseodymium oxide (Pr2O3), cerium oxide (CeO2), neodymium oxide (Nd2O3), promethium oxide (Pm2O3), samarium oxide (Sm2O3), europium oxide (Eu2O3), gadolinium oxide (Gd2O3), terbium oxide (Tb2O3), dysprosium oxide (Dy2O3), holmium oxide (Ho2O3), thulium oxide (Tm2O3), ytterbium oxide (Yb2O3), lutetium oxide (Lu2O3), yttrium oxide (Y2O3), or combinations thereof.

A fence 130 may be provided on the anti-reflection layer 120. The fence 130 may define regions where color filters 140 are provided. The fence 130 may overlap with the isolation layer 102 along the third direction DR3. The fence 130 may include metal or low refractive index material. For example, the low refractive index material may include polymethylmetacrylate (PMMA), silicon acrylate, cellulose acetatebutyrate (CAB), silica, fluoro-silicon acrylate (FSA), or polymer material with dispersed silica particles.

Color filters 140 may be provided on the anti-reflection layer 120. The color filters 140 may be surrounded by the fence 130. In example embodiments, the color filters 140 may include green filters, blue filters, and red filters. In example embodiments, the color filters 140 may include cyan filters, magenta filters, and yellow filters.

A lens layer LL may be provided on the fence 130 and color filters 140. The lens layer LL may include first lenses LS1 and second lenses LS2. In example embodiments, the first lenses LS1 and the second lenses LS2 may be microlenses. The first lenses LS1 may focus incident light onto the first photoelectric conversion regions CR1. The second lenses LS2 may focus incident light onto the second photoelectric conversion regions CR2. The first lenses LS1 and the second lenses LS2 may include resin-based material. For example, the first lenses LS1 and the second lenses LS2 may include styrene-based resin, acrylic-based resin, styrene-acrylic copolymer-based resin, or siloxane-based resin. The first lenses LS1 and the second lenses LS2 will be described in detail below.

The first lenses LS1 may have a thickness equal to or slightly larger than that of the second lenses LS2. For example, the thickness of the first lenses LS1 may be 1.0 to 2.9 times the thickness of the second lenses LS2. The thicknesses of the first lenses LS1 and the second lenses LS2 may be their maximum sizes along the third direction DR3. Compared to when a single first lens LS1 is placed over the first active region AR1, when multiple first lenses LS1 are placed over the first active region AR1 as in the present disclosure, the difference in thickness between the first lens LS1 and the second lens LS2 may be small.

When the thickness difference between the first lens LS1 and the second lens LS2 is large, the difference in focal lengths between the first lens LS1 and the second lens LS2 may also be large. Accordingly, it may be difficult to configure the first lens LS1 and the second lens LS2 so that both incident light passing through the first lens LS1 and incident light passing through the second lens LS2 are focused at required positions. Since the first lenses LS1 and the second lenses LS2 of the present disclosure have a small thickness difference, incident light passing through the first lenses LS1 and incident light passing through the second lenses LS2 can be readily focused at required positions.

When the thickness difference between the first lens LS1 and the second lens LS2 is large, mask pattern formation processes for forming the first lens LS1 and the second lens LS2 are performed separately. Since the first lenses LS1 and the second lenses LS2 of the present disclosure have a small thickness difference, mask patterns for forming the first lenses LS1 and the second lenses LS2 may be formed in the same process step. Accordingly, manpower, cost, and time required for manufacturing the image sensor 10 may be reduced.

Therefore, the present disclosure can provide an image sensor 10 having improved optical characteristics and improved manufacturing process efficiency.

The following describes the first lenses LS1 provided on one first active region AR1.

As shown in FIGS. 4 to 8, multiple first lenses LS1 arranged along the first direction DR1 and the second direction DR2 may be provided over the first active region AR1. From a planar view, each of the multiple first lenses LS1 may have a shape that expands and then narrows when moving from the center portion to the edge portion of the first active region AR1. The shape of each of the multiple first lenses LS1 will be described in detail later. For example, 4 first lenses LS1 arranged in a 2 x 2 configuration along the first direction DR1 and the second direction DR2 may be provided over the first active region AR1. In other example embodiments, the multiple first lenses LS1 over the first active region AR1 may have an arrangement other than 2 x 2 configuration (for example, a 3X3 configuration) along the first direction DR1 and the second direction DR2. A pair of first lenses LS1 immediately adjacent along the first direction DR1 may be connected. In this specification, lenses being connected may mean that a boundary is formed between the lenses. The boundary between a pair of first lenses LS1 immediately adjacent along the first direction DR1 may extend along the second direction DR2. A pair of first lenses LS1 immediately adjacent along the second direction DR2 may be connected. The boundary between a pair of first lenses LS1 immediately adjacent along the second direction DR2 may extend along the first direction DR1.

A lens spacing region LSR may be provided at the center of the 4 first lenses LS1. The lens spacing region LSR may be a region where the first lenses LS1 and the second lenses LS2 are not located. The lens spacing region LSR may be a region that does not overlap with the first lenses LS1 and the second lenses LS2 along the third direction DR3. The lens spacing region LSR may be referred to as a dead zone. Light incident on the lens spacing region LSR may not be focused at required positions (for example, the first photoelectric conversion region CR1 or second photoelectric conversion region CR2). For example, light incident on the lens spacing region LSR may be reflected by the fence 130.

The following describes the first lenses LS1 provided on immediately adjacent first active regions AR1.

A first lens group LSG1, a second lens group LSG2, a third lens group LSG3, and a fourth lens group LSG4 may be provided over 4 first active regions AR1 arranged in a 2 x 2 configuration along the first direction DR1 and the second direction DR2, respectively. The first lens group LSG1, second lens group LSG2, third lens group LSG3, and fourth lens group LSG4 may be arranged in a 2 x 2 configuration. The first lens group LSG1 and the second lens group LSG2 may be arranged sequentially along the first direction DR1. The third lens group LSG3 and fourth lens group LSG4 may be arranged sequentially along the first direction DR1. The third lens group LSG3 and first lens group LSG1 may be arranged sequentially along the second direction DR2. The fourth lens group LSG4 and the second lens group LSG2 may be arranged sequentially along the second direction DR2.

Each of the first lens group LSG1, second lens group LSG2, third lens group LSG3, and fourth lens group LSG4 may include 4 first lenses LS1 arranged in a 2 x 2 configuration along the first direction DR1 and the second direction DR2. In each of the first lens group LSG1, second lens group LSG2, third lens group LSG3, and fourth lens group LSG4, the 4 first lenses LS1 arranged in a 2 x 2 configuration may be referred to as a 1a lens 212(LS1), 1b lens 214(LS1), 1c lens 216(LS1), and 1d lens 218(LS1). The 1a lenses 212(LS1) of the first lens group LSG1, second lens group LSG2, third lens group LSG3, and fourth lens group LSG4 may have substantially the same shape. The 1b lenses 214(LS1) of the first lens group LSG1, second lens group LSG2, third lens group LSG3, and fourth lens group LSG4 may have substantially the same shape. The 1c lenses 216(LS1) of the first lens group LSG1, second lens group LSG2, third lens group LSG3, and fourth lens group LSG4 may have substantially the same shape. The 1d lenses 218(LS1) of the first lens group LSG1, second lens group LSG2, third lens group LSG3, and fourth lens group LSG4 may have substantially the same shape. The 1a lens 212(LS1) and 1b lens 214(LS1) may be arranged sequentially along the first direction DR1. The 1c lens 216(LS1) and 1d lens 218(LS1) may be arranged sequentially along the first direction DR1. The 1c lens 216(LS1) and 1a lens 212(LS1) may be arranged sequentially along the second direction DR2. The 1d lens 218(LS1) and 1b lens 214(LS1) may be arranged sequentially along the second direction DR2.

A pair of first lenses LS1 facing along the first direction DR1 and provided on a pair of first active regions AR1 immediately adjacent along the first direction DR1 may be connected. That is, the 1b lens 214(LS1) of the first lens group LSG1 and the 1a lens 212(LS1) of the second lens group LSG2 may be connected. The 1d lens 218(LS1) of the first lens group LSG1 and the 1c lens 216(LS1) of the second lens group LSG2 may be connected. The 1b lens 214(LS1) of the third lens group LSG3 and the 1a lens 212(LS1) of the fourth lens group LSG4 may be connected. The 1d lens 218(LS1) of the third lens group LSG3 and the 1c lens 216(LS1) of the fourth lens group LSG4 may be connected.

The boundary between a pair of first lenses LS1 facing along the first direction DR1 and provided on a pair of first active regions AR1 immediately adjacent along the first direction DR1 may extend along the second direction DR2. The boundary between the 1b lens 214(LS1) of the first lens group LSG1 and the 1a lens 212(LS1) of the second lens group LSG2 and the boundary between the 1d lens 218(LS1) of the first lens group LSG1 and the 1c lens 216(LS1) of the second lens group LSG2 may extend along the second direction DR2. The boundary between the 1b lens 214(LS1) of the third lens group LSG3 and the 1a lens 212(LS1) of the fourth lens group LSG4 and the boundary between the 1d lens 218(LS1) of the third lens group LSG3 and the 1c lens 216(LS1) of the fourth lens group LSG4 may extend along the second direction DR2.

A lens spacing region LSR may be provided between the first lens group LSG1 and the second lens group LSG2. The lens spacing region LSR may be provided between the 1b lens 214(LS1) of the first lens group LSG1, the 1d lens 218(LS1) of the first lens group LSG1, the 1a lens 212(LS1) of the second lens group LSG2, and the 1c lens 216(LS1) of the second lens group LSG2. A lens spacing region LSR may be provided between the third lens group LSG3 and the fourth lens group LSG4. The lens spacing region LSR may be provided between the 1b lens 214(LS1) of the third lens group LSG3, the 1d lens 218(LS1) of the third lens group LSG3, the 1a lens 212(LS1) of the fourth lens group LSG4, and the 1c lens 216(LS1) of the fourth lens group LSG4.

A pair of first lenses LS1 facing along the second direction DR2 and provided on a pair of first active regions AR1 immediately adjacent along the second direction DR2 may be connected. The 1c lens 216(LS1) of the first lens group LSG1 and the 1a lens 212(LS1) of the third lens group LSG3 may be connected. The 1d lens 218(LS1) of the first lens group LSG1 and the 1b lens 214(LS1) of the third lens group LSG3 may be connected. The 1c lens 216(LS1) of the second lens group LSG2 and the 1a lens 212(LS1) of the fourth lens group LSG4 may be connected. The 1d lens 218(LS1) of the second lens group LSG2 and the 1b lens 214(LS1) of the fourth lens group LSG4 may be connected.

The boundary between a pair of first lenses LS1 facing along the second direction DR2 and provided on a pair of first active regions AR1 immediately adjacent along the second direction DR2 may extend along the first direction DR1. The boundary between the 1c lens 216(LS1) of the first lens group LSG1 and the 1a lens 212(LS1) of the third lens group LSG3 and the boundary between the 1d lens 218(LS1) of the first lens group LSG1 and the 1b lens 214(LS1) of the third lens group LSG3 may extend along the first direction DR1. The boundary between the 1c lens 216(LS1) of the second lens group LSG2 and the 1a lens 212(LS1) of the fourth lens group LSG4 and the boundary between the 1d lens 218(LS1) of the second lens group LSG2 and the 1b lens 214(LS1) of the fourth lens group LSG4 may extend along the first direction DR1.

A lens spacing region LSR may be provided between the first lens group LSG1 and the third lens group LSG3. The lens spacing region LSR may be provided between the 1c lens 216(LS1) of the first lens group LSG1, the 1d lens 218(LS1) of the first lens group LSG1, the 1a lens 212(LS1) of the third lens group LSG3, and the 1b lens 214(LS1) of the third lens group LSG3. A lens spacing region LSR may be provided between the second lens group LSG2 and the fourth lens group LSG4. The lens spacing region LSR may be provided between the 1c lens 216(LS1) of the second lens group LSG2, the 1d lens 218(LS1) of the second lens group LSG2, the 1a lens 212(LS1) of the fourth lens group LSG4, and the 1b lens 214(LS1) of the fourth lens group LSG4. From a planar view, the lens spacing region LSR between the first lens group LSG1 and the second lens group LSG2, the lens spacing region LSR between the third lens group LSG3 and the fourth lens group LSG4, the lens spacing region LSR between the first lens group LSG1 and the third lens group LSG3, and the lens spacing region LSR between the second lens group LSG2 and the fourth lens group LSG4 may have substantially the same areas as each other.

A lens spacing region LSR may be provided between the 1a lens 212(LS1), the 1b lens 214(LS1), the 1c lens 216(LS1), and the 1d lens 218(LS1) in each of the first lens group LSG1, the second lens group LSG2, the third lens group LSG3, and the fourth lens group LSG4. From a planar view, the lens spacing region LSR between the 1a lens 212(LS1), 1b lens 214(LS1), 1c lens 216(LS1), and 1d lens 218(LS1) may have a larger area than the lens spacing region LSR between the first lens group LSG1 and the second lens group LSG2, the lens spacing region LSR between the third lens group LSG3 and fourth lens group LSG4, the lens spacing region LSR between the first lens group LSG1 and third lens group LSG3, and the lens spacing region LSR between the second lens group LSG2 and fourth lens group LSG4.

From a planar view, each of the 1a lens 212(LS1), 1b lens 214(LS1), 1c lens 216(LS1), and 1d lens 218(LS1) may have a shape that expands and then narrows when moving from the center portion to the edge portion of the first active region AR1. For example, the shapes of the 1a lens 212(LS1) of the fourth lens group LSG4, the 1b lens 214(LS1) of the third lens group LSG3, the 1c lens 216(LS1) of the second lens group LSG2, and the 1d lens 218(LS1) of the first lens group LSG1 are described.

The width of the 1a lens 212(LS1) of the fourth lens group LSG4 along the fourth direction DR4 may increase as it moves away from the center of the fourth lens group LSG4 in the opposite direction of the fifth direction DR5. The width of the 1a lens 212(LS1) of the fourth lens group LSG4 along the fourth direction DR4 may decrease as it moves in the opposite direction of the fifth direction DR5 in the region adjacent to the second active region AR2 between the first lens group LSG1, second lens group LSG2, third lens group LSG3, and fourth lens group LSG4.

The width of the 1b lens 214(LS1) of the third lens group LSG3 along the fifth direction DR5 may increase as it moves away from the center of the third lens group LSG3 along the fourth direction DR4. The width of the 1b lens 214(LS1) of the third lens group LSG3 along the fifth direction DR5 may decrease as it moves along the fourth direction DR4 in the region adjacent to the second active region AR2 between the first lens group LSG1, second lens group LSG2, third lens group LSG3, and fourth lens group LSG4.

The width of the 1c lens 216(LS1) of the second lens group LSG2 along the fifth direction DR5 may increase as it moves away from the center of the second lens group LSG2 in the opposite direction of the fourth direction DR4. The width of the 1c lens 216(LS1) of the second lens group LSG2 along the fifth direction DR5 may decrease as it moves in the opposite direction of the fourth direction DR4 in the region adjacent to the second active region AR2 between the first lens group LSG1, second lens group LSG2, third lens group LSG3, and fourth lens group LSG4.

The width of the 1d lens 218(LS1) of the first lens group LSG1 along the fourth direction DR4 may increase as it moves away from the center of the first lens group LSG1 along the fifth direction DR5. The width of the 1d lens 218(LS1) of the first lens group LSG1 along the fourth direction DR4 may decrease as it moves along the fifth direction DR5 in the region adjacent to the second active region AR2 between the first lens group LSG1, second lens group LSG2, third lens group LSG3, and fourth lens group LSG4.

The following describes the second lens LS2 and first lenses LS1 provided over the second active region AR2 and four first active regions AR1 surrounding the second active region AR2, respectively.

One of the four first lenses LS1 provided over each of the first active regions AR1 may be connected to the second lens LS2. The 1d lens 218(LS1) of the first lens group LSG1, the 1c lens 216(LS1) of the second lens group LSG2, the 1b lens 214(LS1) of the third lens group LSG3, and the 1a lens 212(LS1) of the fourth lens group LSG4 may be connected to the second lens LS2 located between the first to fourth lens groups LSG1 to LSG4.

The 1d lens 218(LS1) of the first lens group LSG1, the second lens LS2, and the 1a lens 212(LS1) of the fourth lens group LSG4 may be sequentially connected along the fifth direction DR5. The boundary between the 1d lens 218(LS1) of the first lens group LSG1 and the second lens LS2 and the boundary between the 1a lens 212(LS1) of the fourth lens group LSG4 and the second lens LS2 may be substantially parallel to each other. The boundary between the 1d lens 218(LS1) of the first lens group LSG1 and the second lens LS2 and the boundary between the 1a lens 212(LS1) of the fourth lens group LSG4 and the second lens LS2 may extend along the fourth direction DR4. The fourth direction DR4 and the fifth direction DR5 may be substantially parallel to the first surface 100a.

The 1c lens 216(LS1) of the second lens group LSG2, the second lens LS2, and the 1b lens 214(LS1) of the third lens group LSG3 may be sequentially connected along the fourth direction DR4. The boundary between the 1c lens 216(LS1) of the second lens group LSG2 and the second lens LS2 and the boundary between the 1b lens 214(LS1) of the third lens group LSG3 and the second lens LS2 may be substantially parallel to each other. The boundary between the 1c lens 216(LS1) of the second lens group LSG2 and the second lens LS2 and the boundary between the 1b lens 214(LS1) of the third lens group LSG3 and the second lens LS2 may extend along the fifth direction DR5.

The remaining three of the four first lenses LS1 provided over each of the first active regions AR1 may be spaced apart from the second lens LS2 located between the first to fourth lens groups LSG1 to LSG4. The 1a, 1b, and 1c lenses 212(LS1), 214(LS1), 216(LS1) of the first lens group LSG1, the 1a, 1b, and 1d lenses 212(LS1), 214(LS1), 218(LS1) of the second lens group LSG2, the 1a, 1c, and 1d lenses 212(LS1), 216(LS1), 218(LS1) of the third lens group LSG3, and the 1b, 1c, and 1d lenses 214(LS1), 216(LS1), 218(LS1) of the fourth lens group LSG4 may be spaced apart from the second lens LS2 located between the first to fourth lens groups LSG1 to LSG4.

The present disclosure can provide an image sensor having improved optical characteristics and improved manufacturing process efficiency.

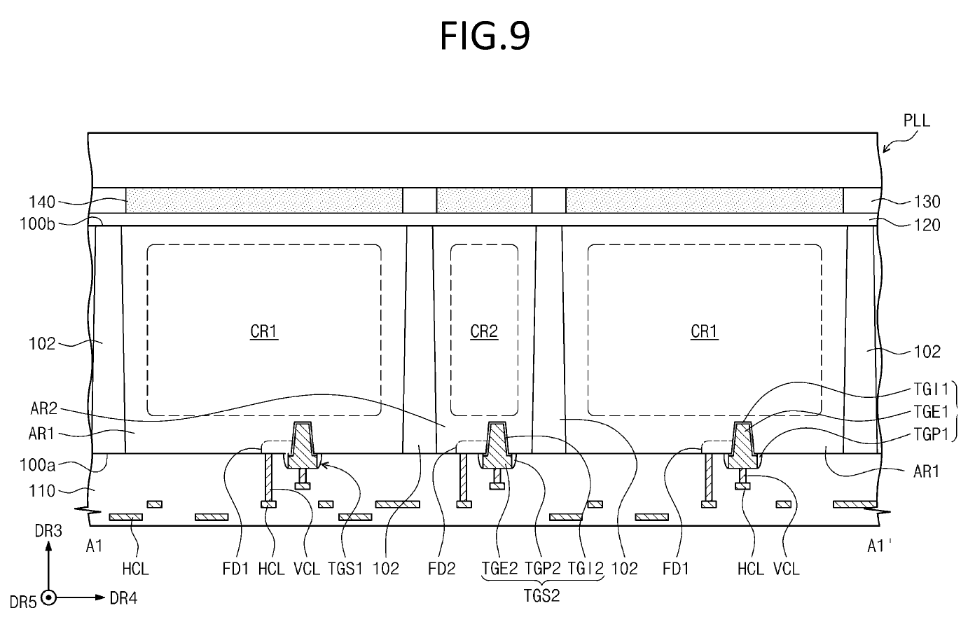

FIGS. 9 to 12 are cross-sectional views corresponding to FIG. 7 that illustrates a method of manufacturing the lens layer of the image sensor described with reference to FIGS. 4 to 8. For brevity of explanation, substantially identical content to that described with reference to FIGS. 4 to 8 may not be described.

Referring to FIG. 9, a preliminary lens layer PLL may be formed on the color filters 140 and fence 130 described with reference to FIGS. 4 to 8. In example embodiments, the preliminary lens layer PLL may be formed by a coating process. For example, the coating process may include a spin coating process, slot die coating process, or spray coating process. The preliminary lens layer PLL may include resin-based material. For example, the preliminary lens layer PLL may include styrene-based resin, acrylic-based resin, styrene-acrylic copolymer-based resin, or siloxane-based resin.

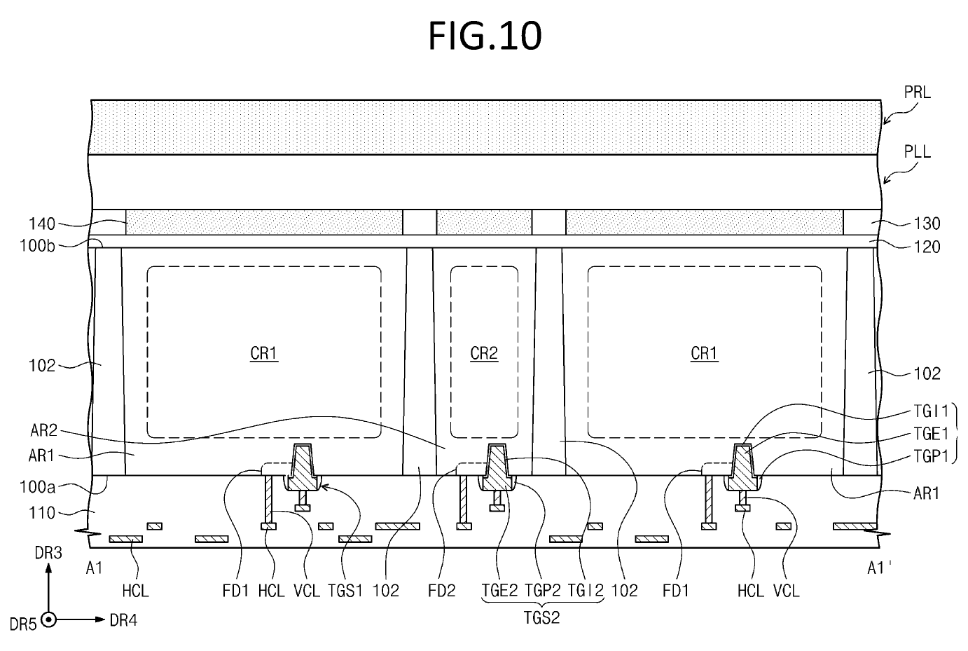

Referring to FIG. 10, a photoresist layer PRL may be formed on the preliminary lens layer PLL. For example, the photoresist layer PRL may be formed by a coating process. For example, the coating process may include a spin coating process, slot die coating process, or spray coating process.

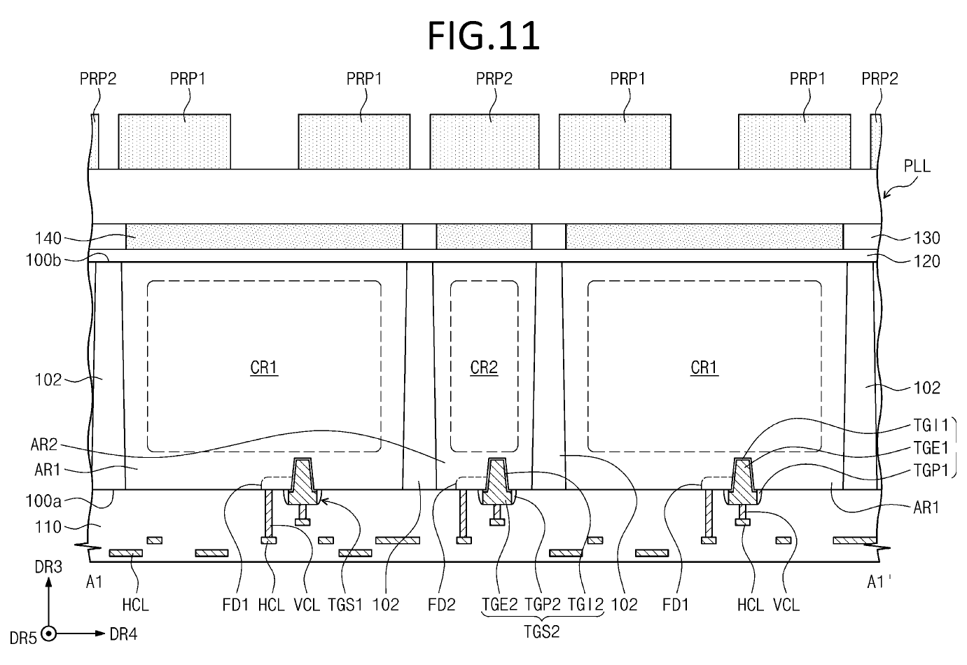

Referring to FIG. 11, first photoresist patterns PRP1 and second photoresist patterns PRP2 may be formed. Forming the first photoresist patterns PRP1 and the second photoresist patterns PRP2 may include exposing required regions of the photoresist layer PRL to light in an exposure process and removing either exposed portions or unexposed portions in a development process.

The first photoresist patterns PRP1 may be formed over the first active regions AR1. Multiple first photoresist patterns PRP1 may be formed over one first active region AR1. The arrangement and number of first photoresist patterns PRP1 formed over the first active region AR1 may be identical to the arrangement and number of first lenses LS1 to be formed over the first active region AR1 in a subsequent step. For example, 4 first photoresist patterns PRP1 arranged in a 2 x 2 configuration may be formed to form 4 first lenses LS1 arranged in a 2 x 2 configuration over the first active region AR1. The first photoresist patterns PRP1 may be spaced apart. In example embodiments, the preliminary lens layer PLL may be exposed between the first photoresist patterns PRP1.

The second photoresist patterns PRP2 may be formed over each of the second active regions AR2. Each of the second photoresist patterns PRP2 may be surrounded by the first photoresist patterns PLP1. The second photoresist patterns PRP2 may be spaced apart from immediately adjacent first photoresist patterns PRP1. In example embodiments, the preliminary lens layer PLL may be exposed between the second photoresist patterns PRP2 and their immediately adjacent first photoresist patterns PRP1. The first photoresist patterns PRP1 and the second photoresist patterns PRP2 may have substantially the same thickness.

The second photoresist pattern PRP2 between the first active regions AR1 may be arranged along the fourth direction DR4 or fifth direction DR5 that intersects with the first direction DR1 and the second direction DR2 with the first photoresist pattern PRP1 immediately adjacent to the second photoresist pattern PRP2. When the distance between the second photoresist pattern PRP2 and its immediately adjacent first photoresist pattern PRP1 is too large, the second lens LS2 may be formed larger than required in the subsequent first lens LS1 and second lens LS2 formation process. If the distance between the second photoresist pattern PRP2 and its immediately adjacent first photoresist pattern PRP1 is sufficiently small, it can prevent the first lenses LS1 surrounding the second lens LS2 from being formed larger than the required size of the second lens LS2 in the first lens LS1 and the second lens LS2 formation process. Therefore, the distance between the second photoresist pattern PRP2 and its immediately adjacent first photoresist pattern PRP1 may be determined so that the second lens LS2 is formed to the required size in the subsequent first lens LS1 and second lens LS2 formation process.

When the first photoresist patterns PRP1 are arranged along the fourth direction DR4 and fifth direction DR5 over each of the active regions AR1, it may be difficult to make the distance between the second photoresist pattern PRP2 and its immediately adjacent first photoresist pattern PRP1 sufficiently small. When the first photoresist patterns PRP1 are arranged along the first direction DR1 and the second direction DR2 over each of the first active regions AR1, the distance between the second photoresist pattern PRP2 and its immediately adjacent first photoresist pattern PRP1 may be sufficiently small. Accordingly, the second lens LS2 may be formed to the required size.

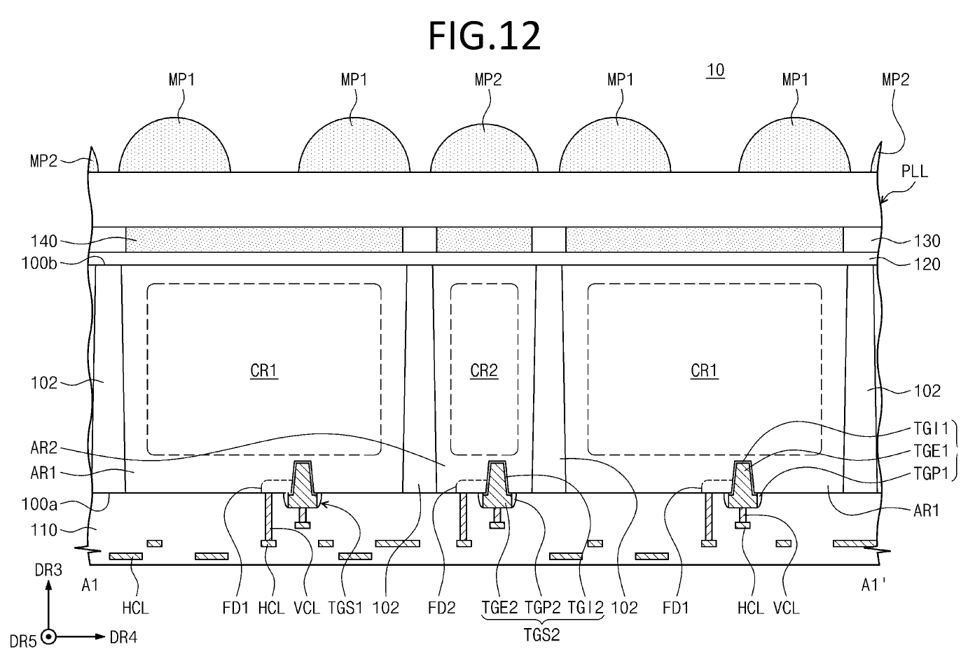

Referring to FIG. 12, first mask patterns MP1 and second mask patterns MP2 may be formed by performing a reflow process on the first photoresist patterns PRP1 and the second photoresist patterns PRP2. The reflow process may include heat-treating the reflow target (first photoresist patterns PRP1 and second photoresist patterns PRP2) at required temperature and time. During the reflow process, the first photoresist patterns PRP1 and the second photoresist patterns PRP2 may be deformed into first mask patterns MP1 and second mask patterns MP2 having rounded shapes, respectively. The first mask patterns MP1 and the second mask patterns MP2 may be spaced apart. For example, the second mask pattern MP2 may be spaced apart from its immediately adjacent first mask patterns MP1. For example, immediately adjacent first mask patterns MP1 may be spaced apart. The preliminary lens layer PLL may be exposed between the first mask patterns MP1 and the second mask patterns MP2. The first mask patterns MP1 may have a thickness equal to or slightly larger than that of the second mask patterns MP2. For example, the thickness of the first mask patterns MP1 may be 1.0 to 2.9 times the thickness of the second mask patterns MP2.

Referring to FIG. 7, first lenses LS1 and second lenses LS2 may be formed by performing an etch-back process on the preliminary lens layer PLL using first mask patterns MP1 and second mask patterns MP2. Four first lenses LS1 provided on each of the first active regions AR1 may be arranged along the first direction DR1 and the second direction DR2. Unlike the second mask pattern MP2 being spaced apart from immediately adjacent first mask patterns MP1, the second lens LS2 may be connected to immediately adjacent first lenses LS1. For example, one of four first lenses LS1 provided on each of the first active regions AR1 may be connected to the second lens LS2 located between the first active regions AR1, and the remaining three first lenses LS1 may be spaced apart from the second lens LS2 located between the first active regions AR1. Four first lenses LS1 surrounding the second lens LS2 may prevent the second lens LS2 from being formed larger than required during the etch-back process. Accordingly, the second lens LS2 may have the required size.

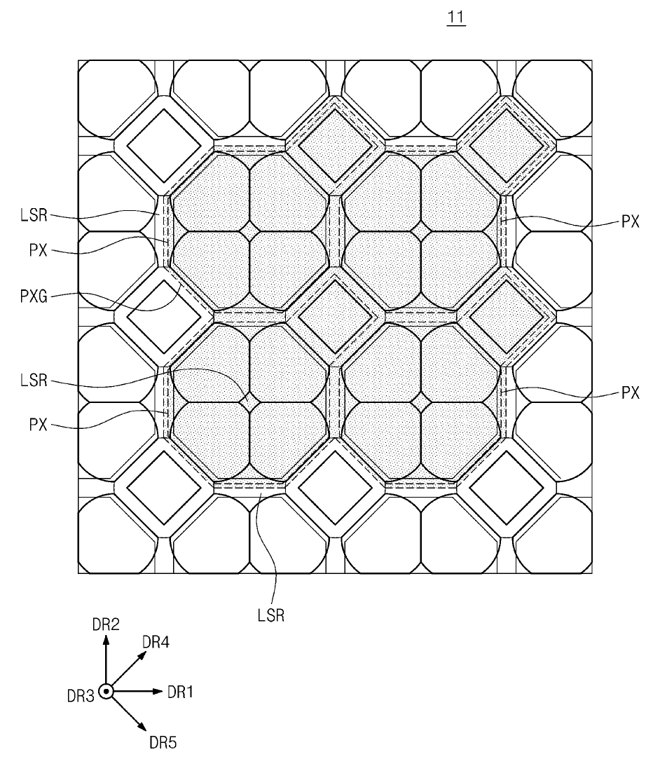

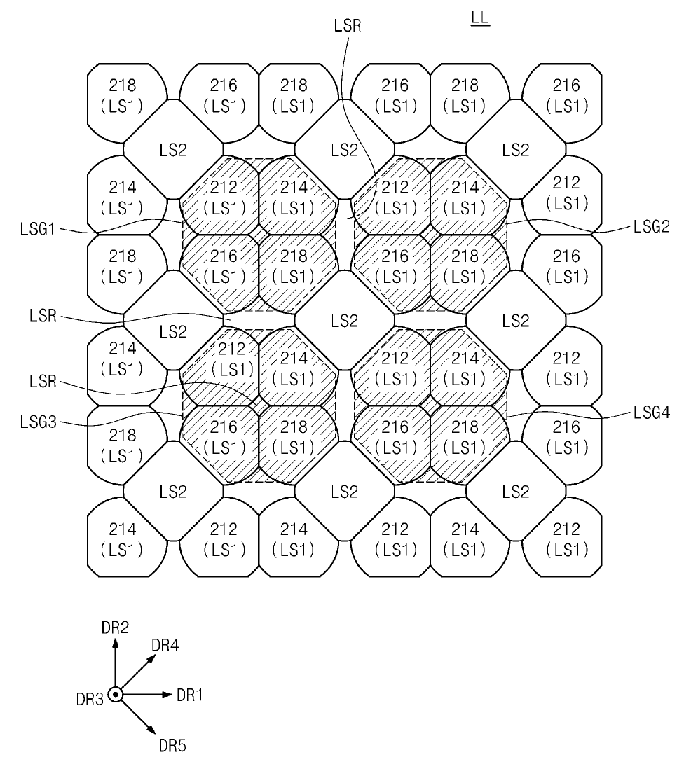

FIG. 13 is a plan view of an image sensor according to example embodiments. FIG. 14 is a plan view of the lens layer of FIG. 13. For conciseness, differences from what was described with reference to FIGS. 4 to 8 are explained.

FIGS. 13 and 14 illustrate the image sensor 11. Unlike what was described with reference to FIGS. 4 to 8, pairs of first lenses LS1, which are provided on each of a pair of first active regions AR1 (immediately adjacent to each other along the first direction DR1 and face along the first direction DR1), may be spaced apart. That is, the 1b lens 214(LS1) of the first lens group LSG1 and the 1a lens 212(LS1) of the second lens group LSG2 may be spaced apart. The 1d lens 218(LS1) of the first lens group LSG1 and the 1c lens 216(LS1) of the second lens group LSG2 may be spaced apart. The 1b lens 214(LS1) of the third lens group LSG3 and the 1a lens 212(LS1) of the fourth lens group LSG4 may be spaced apart. The 1d lens 218(LS1) of the third lens group LSG3 and the 1c lens 216(LS1) of the fourth lens group LSG4 may be spaced apart.

The lens spacing region LSR between the first lens group LSG1 and the second lens group LSG2 may extend further between a pair of first lenses LS1 that are included in the first lens group LSG1 and the second lens group LSG2, respectively, and face along the first direction DR1. The lens spacing region LSR may extend further between the 1b lens 214(LS1) of the first lens group LSG1 and the 1a lens 212(LS1) of the second lens group LSG2. The lens spacing region LSR may extend further between the 1d lens 218(LS1) of the first lens group LSG1 and the 1c lens 216(LS1) of the second lens group LSG2. The lens spacing region LSR between the first lens group LSG1 and the second lens group LSG2 may contact the second lens LS2 between the 1b lens 214(LS1) of the first lens group LSG1 and the 1a lens 212(LS1) of the second lens group LSG2 and the second lens LS2 between the 1d lens 218(LS1) of the first lens group LSG1 and the 1c lens 216(LS1) of the second lens group LSG2.

The lens spacing region LSR between the third lens group LSG3 and the fourth lens group LSG4 may extend further between a pair of first lenses LS1 that are included in the third lens group LSG3 and the fourth lens group LSG4, respectively, and face along the first direction DR1. The lens spacing region LSR may extend further between the 1b lens 214(LS1) of the third lens group LSG3 and the 1a lens 212(LS1) of the fourth lens group LSG4. The lens spacing region LSR may extend further between the 1d lens 218(LS1) of the third lens group LSG3 and the 1c lens 216(LS1) of the fourth lens group LSG4. The lens spacing region LSR between the third lens group LSG3 and the fourth lens group LSG4 may contact the second lens LS2 between the 1b lens 214(LS1) of the third lens group LSG3 and the 1a lens 212(LS1) of the fourth lens group LSG4 and the second lens LS2 between the 1d lens 218(LS1) of the third lens group LSG3 and the 1c lens 216(LS1) of the fourth lens group LSG4.

A pair of first lenses LS1 that are provided on each of a pair of first active regions AR1 immediately adjacent to each other along the second direction DR2 and face along the second direction DR2 may be spaced apart. The 1c lens 216(LS1) of the first lens group LSG1 and the 1a lens 212(LS1) of the third lens group LSG3 may be spaced apart. The 1d lens 218(LS1) of the first lens group LSG1 and the 1b lens 214(LS1) of the third lens group LSG3 may be spaced apart. The 1c lens 216(LS1) of the second lens group LSG2 and the 1a lens 212(LS1) of the fourth lens group LSG4 may be spaced apart. The 1d lens 218(LS1) of the second lens group LSG2 and the 1b lens 214(LS1) of the fourth lens group LSG4 may be spaced apart.

The lens spacing region LSR between the first lens group LSG1 and the third lens group LSG3 may extend further between a pair of first lenses LS1 that are included in the first lens group LSG1 and the third lens group LSG3, respectively, and face along the second direction DR2. The lens spacing region LSR may extend further between the 1c lens 216(LS1) of the first lens group LSG1 and the 1a lens 212(LS1) of the third lens group LSG3. The lens spacing region LSR may extend further between the 1d lens 218(LS1) of the first lens group LSG1 and the 1b lens 214(LS1) of the third lens group LSG3. The lens spacing region LSR between the first lens group LSG1 and the third lens group LSG3 may contact the second lens LS2 between the 1c lens 216(LS1) of the first lens group LSG1 and the 1a lens 212(LS1) of the third lens group LSG3 and the second lens LS2 between the 1d lens 218(LS1) of the first lens group LSG1 and the 1b lens 214(LS1) of the third lens group LSG3.

The lens spacing region LSR between the second lens group LSG2 and the fourth lens group LSG4 may extend further between a pair of first lenses LS1 that are included in the second lens group LSG2 and the fourth lens group LSG4, respectively, and face along the second direction DR2. The lens spacing region LSR may extend further between the 1c lens 216(LS1) of the second lens group LSG2 and the 1a lens 212(LS1) of the fourth lens group LSG4. The lens spacing region LSR may extend further between the 1d lens 218(LS1) of the second lens group LSG2 and the 1b lens 214(LS1) of the fourth lens group LSG4. The lens spacing region LSR between the first lens group LSG1 and the third lens group LSG3 may contact the second lens LS2 between the 1c lens 216(LS1) of the first lens group LSG1 and the 1a lens 212(LS1) of the third lens group LSG3 and the second lens LS2 between the 1d lens 218(LS1) of the first lens group LSG1 and the 1b lens 214(LS1) of the third lens group LSG3.

From a planar perspective, the lens spacing region LSR between the first lens group LSG1 and the second lens group LSG2, the lens spacing region LSR between the third lens group LSG3 and the fourth lens group LSG4, the lens spacing region LSR between the first lens group LSG1 and the third lens group LSG3, and the lens spacing region LSR between the second lens group LSG2 and the fourth lens group LSG4 may have a larger area than the lens spacing region LSR between the 1a lens 212(LS1), the 1b lens 214(LS1), the 1c lens 216(LS1), and the 1d lens 218(LS1).

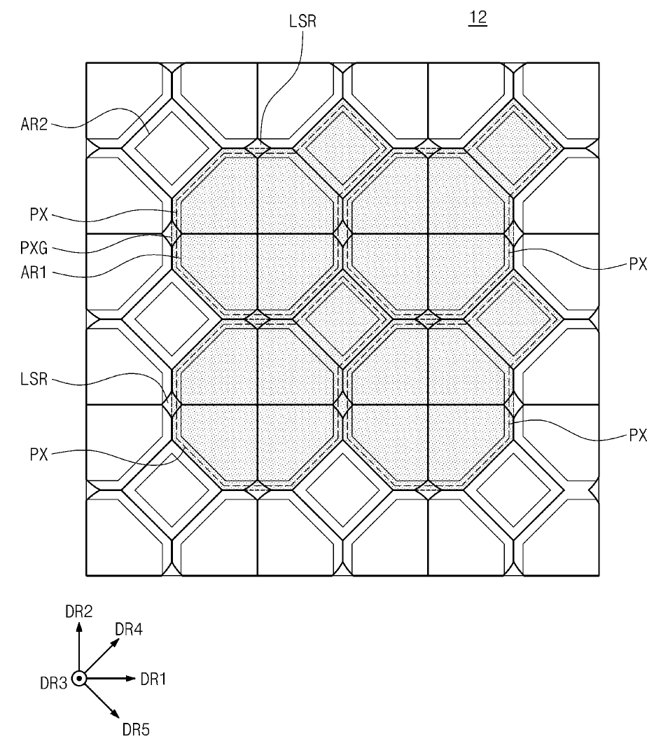

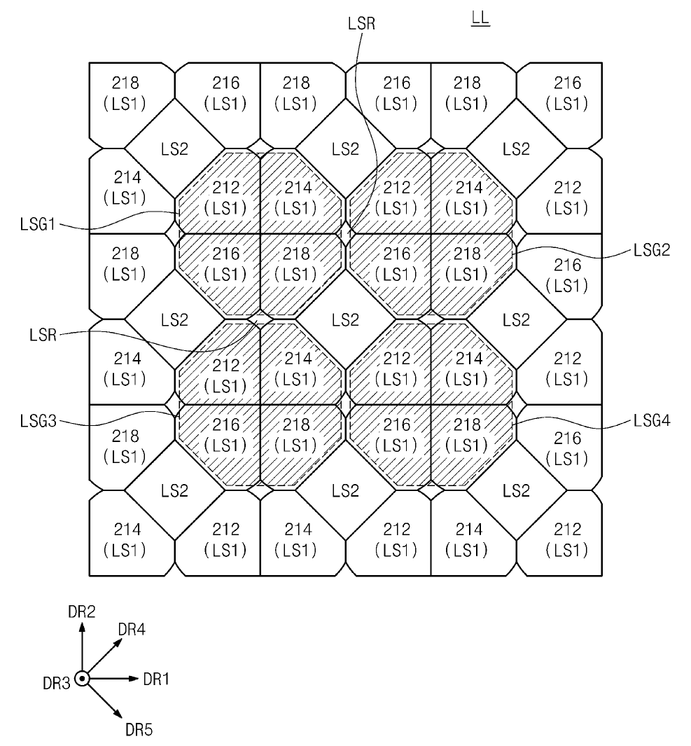

FIG. 15 is a plan view of an image sensor according to example embodiments. FIG. 16 is a plan view of the lens layer of FIG. 15. For conciseness, differences from what was described with reference to FIGS. 4 to 8 are explained.

Referring to FIGS. 15 and 16, image sensor 12 may be provided. Unlike what was described with reference to FIGS. 4 to 8, four first lenses LS1 provided on one first active region AR1 may be connected at the center. A lens spacing region LSR may not be provided between the 1a lens 212(LS1), the 1b lens 214(LS1), the 1c lens 216(LS1), and the 1d lens 218(LS1).

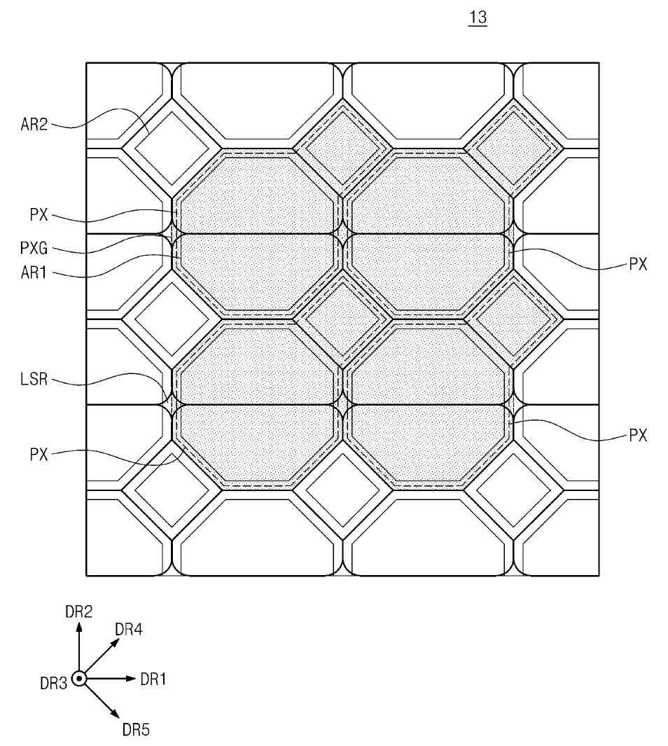

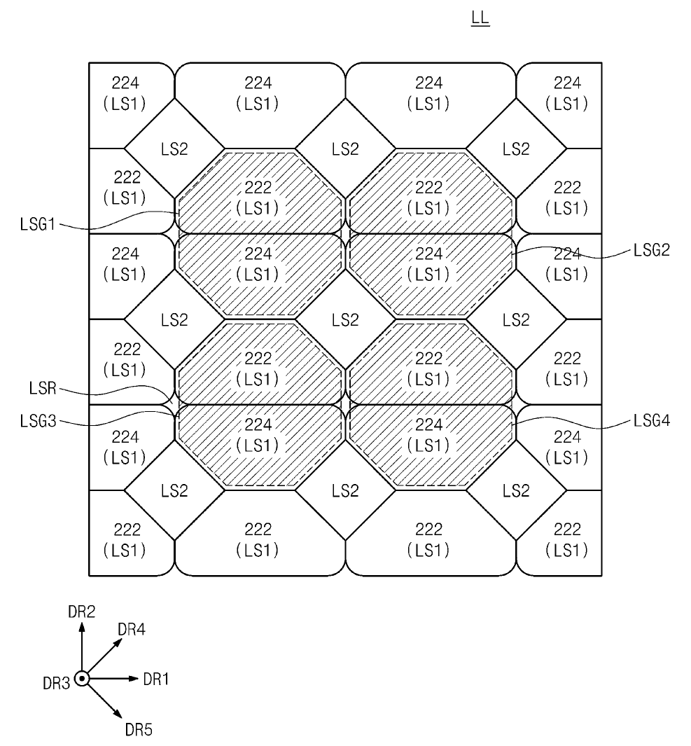

FIG. 17 is a plan view of an image sensor according to example embodiments. FIG. 18 is a plan view of the lens layer of FIG. 17. For conciseness, differences from what was described with reference to FIGS. 4 to 8 are explained.

Referring to FIGS. 17 and 18, image sensor 13 may be provided. Unlike what was described with reference to FIGS. 4 to 8, two first lenses LS1 arranged along the second direction DR2 may be provided on each of the first active regions AR1. The first lenses LS1 may extend along the first direction DR1. A pair of first lenses LS1 immediately adjacent to each other along the second direction DR2 may be connected. The boundary between a pair of first lenses LS1 immediately adjacent to each other along the second direction DR2 may extend along the first direction DR1.

In each of the first lens group LSG1, the second lens group LSG2, the third lens group LSG3, and the fourth lens group LSG4, two first lenses LS1 arranged along the second direction DR2 may be referred to as a 2a lens 222(LS1) and a 2b lens 224(LS1). The 2b lens 224(LS1) and the 2a lens 222(LS1) may be arranged sequentially along the second direction DR2.

A pair of first lenses LS1 that are provided on each of a pair of first active regions AR1 immediately adjacent to each other along the first direction DR1 and face along the first direction DR1 may be connected. The 2a lens 222(LS1) of the first lens group LSG1 and the 2a lens 222(LS1) of the second lens group LSG2 may be connected. The 2b lens 224(LS1) of the first lens group LSG1 and the 2b lens 224(LS1) of the second lens group LSG2 may be connected. The 2a lens 222(LS1) of the third lens group LSG3 and the 2a lens 222(LS1) of the fourth lens group LSG4 may be connected. The 2b lens 224(LS1) of the third lens group LSG3 and the 2b lens 224(LS1) of the fourth lens group LSG4 may be connected.

The boundary between a pair of first lenses LS1 that are provided on each of a pair of first active regions AR1 immediately adjacent to each other along the first direction DR1 and face along the first direction DR1 may extend along the second direction DR2. The boundary between the 2a lens 222(LS1) of the first lens group LSG1 and the 2a lens 222(LS1) of the second lens group LSG2 and the boundary between the 2b lens 224(LS1) of the first lens group LSG1 and the 2b lens 224(LS1) of the second lens group LSG2 may extend along the second direction DR2. The boundary between the 2a lens 222(LS1) of the third lens group LSG3 and the 2a lens 222(LS1) of the fourth lens group LSG4 and the boundary between the 2b lens 224(LS1) of the third lens group LSG3 and the 2b lens 224(LS1) of the fourth lens group LSG4 may extend along the second direction DR2.

A lens spacing region LSR may be provided between the first lens group LSG1 and the second lens group LSG2. The lens spacing region LSR may be provided between the 2a lens 222(LS1) of the first lens group LSG1, the 2b lens 224(LS1) of the first lens group LSG1, the 2a lens 222(LS1) of the second lens group LSG2, and the 2b lens 224(LS1) of the second lens group LSG2. A lens spacing region LSR may be provided between the third lens group LSG3 and the fourth lens group LSG4. The lens spacing region LSR may be provided between the 2a lens 222(LS1) of the third lens group LSG3, the 2b lens 224(LS1) of the third lens group LSG3, the 2a lens 222(LS1) of the fourth lens group LSG4, and the 2b lens 224(LS1) of the fourth lens group LSG4. In example embodiments, from a planar perspective, the lens spacing region LSR between the first lens group LSG1 and the second lens group LSG2 and the lens spacing region LSR between the third lens group LSG3 and the fourth lens group LSG4 may have substantially the same area.

A pair of first lenses LS1 that are provided on each of a pair of first active regions AR1 immediately adjacent to each other along the second direction DR2 and face along the second direction DR2 may be connected. The 2b lens 224(LS1) of the first lens group LSG1 and the 2a lens 222(LS1) of the third lens group LSG3 may be connected. The 2b lens 224(LS1) of the second lens group LSG2 and the 2a lens 222(LS1) of the fourth lens group LSG4 may be connected.

The boundary between a pair of first lenses LS1 that are provided on each of a pair of first active regions AR1 immediately adjacent to each other along the second direction DR2 and face along the second direction DR2 may extend along the first direction DR1. The boundary between the 2b lens 224(LS1) of the first lens group LSG1 and the 2a lens 222(LS1) of the third lens group LSG3 may extend along the first direction DR1. The boundary between the 2b lens 224(LS1) of the second lens group LSG2 and the 2a lens 222(LS1) of the fourth lens group LSG4 may extend along the first direction DR1.

One of two first lenses LS1 provided on each of the first active regions AR1 may be connected to the second lens LS2. The 2b lens 224(LS1) of the first lens group LSG1, the 2b lens 224(LS1) of the second lens group LSG2, the 2a lens 222(LS1) of the third lens group LSG3, and the 2a lens 222(LS1) of the fourth lens group LSG4 may be connected to the second lens LS2.

The 2b lens 224(LS1) of the first lens group LSG1, the second lens LS2, and the 2a lens 222(LS1) of the fourth lens group LSG4 may be sequentially connected along the fifth direction DR5. The boundary between the 2b lens 224(LS1) of the first lens group LSG1 and the second lens LS2 and the boundary between the 2a lens 222(LS1) of the fourth lens group LSG4 and the second lens LS2 may be substantially parallel to each other. The boundary between the 2b lens 224(LS1) of the first lens group LSG1 and the second lens LS2 and the boundary between the 2a lens 222(LS1) of the fourth lens group LSG4 and the second lens LS2 may extend along the fourth direction DR4.

The 2b lens 224(LS1) of the second lens group LSG2, the second lens LS2, and the 2a lens 222(LS1) of the third lens group LSG3 may be sequentially connected along the fourth direction DR4. The boundary between the 2b lens 224(LS1) of the second lens group LSG2 and the second lens LS2 and the boundary between the 2a lens 222(LS1) of the third lens group LSG3 and the second lens LS2 may be substantially parallel to each other. The boundary between the 2b lens 224(LS1) of the second lens group LSG2 and the second lens LS2 and the boundary between the 2a lens 222(LS1) of the third lens group LSG3 and the second lens LS2 may extend along the fifth direction DR5.

The remaining one of two first lenses LS1 provided on each of the first active regions AR1 may be spaced apart from the second lens LS2 located between the first to fourth lens groups LSG1 to LSG4. The 2a lens 222(LS1) of the first lens group LSG1, the 2a lens 222(LS1) of the second lens group LSG2, the 2b lens 224(LS1) of the third lens group LSG3, and the 2b lens 224(LS1) of the fourth lens group LSG4 may be spaced apart from the second lens LS2 located between the first to fourth lens groups LSG1 to LSG4.

The width of the 2a lens 222(LS1) along the first direction DR1 may increase along the second direction DR2 between a pair of lens spacing regions LSR immediately adjacent to each other along the first direction DR1, and may decrease along the second direction DR2 between a pair of second lenses LS2 immediately adjacent to each other along the first direction DR1. The width of the 2a lens 222(LS1) along the first direction DR1 may be constant between the lens spacing region LSR and the second lens LS2 immediately adjacent to each other along the second direction DR2.

The width of the 2b lens 224(LS1) along the first direction DR1 may increase along the second direction DR2 between a pair of second lenses LS2 immediately adjacent to each other along the first direction DR1, and may decrease along the second direction DR2 between a pair of lens spacing regions LSR immediately adjacent to each other along the first direction DR1. The width of the 2b lens 224(LS1) along the first direction DR1 may be constant between the lens spacing region LSR and the second lens LS2 immediately adjacent to each other along the second direction DR2.

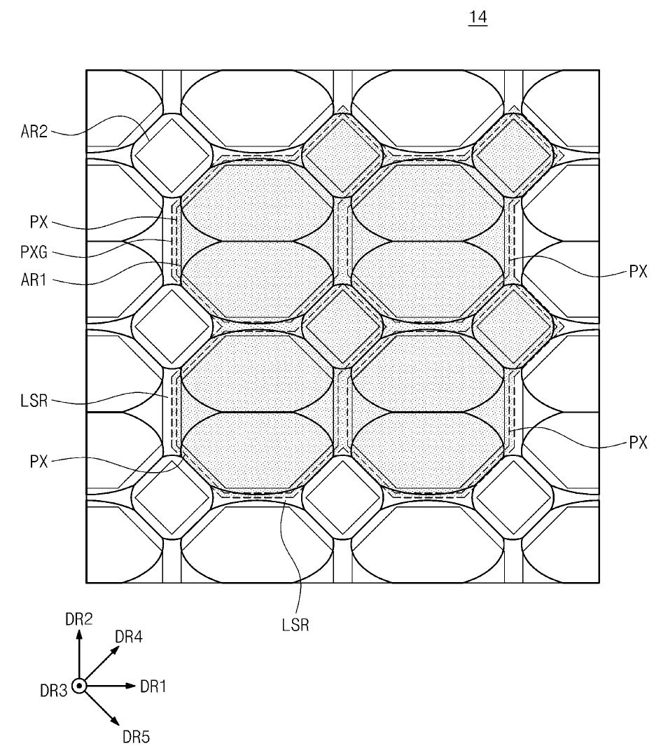

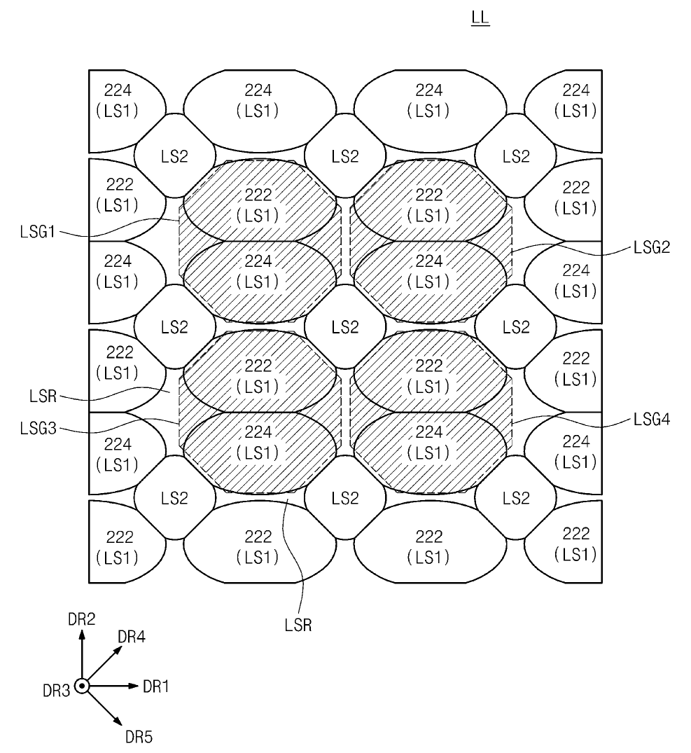

FIG. 19 is a plan view of an image sensor according to example embodiments. FIG. 20 is a plan view of the lens layer of FIG. 19. For conciseness, differences from what was described with reference to FIGS. 17 and 18 are explained.

Referring to FIGS. 19 and 20, image sensor 14 may be provided. Unlike what was described with reference to FIGS. 17 and 18, a pair of first lenses LS1 that are provided on each of a pair of first active regions AR1 immediately adjacent to each other along the first direction DR1 and face along the first direction DR1 may be spaced apart. The 2a lens 222(LS1) of the first lens group LSG1 and the 2a lens 222(LS1) of the second lens group LSG2 may be spaced apart. The 2b lens 224(LS1) of the first lens group LSG1 and the 2b lens 224(LS1) of the second lens group LSG2 may be spaced apart. The 2a lens 222(LS1) of the third lens group LSG3 and the 2a lens 222(LS1) of the fourth lens group LSG4 may be spaced apart. The 2b lens 224(LS1) of the third lens group LSG3 and the 2b lens 224(LS1) of the fourth lens group LSG4 may be spaced apart.

The lens spacing region LSR between the first lens group LSG1 and the second lens group LSG2 may extend further between a pair of first lenses LS1 that are included in the first lens group LSG1 and the second lens group LSG2, respectively, and face along the first direction DR1. The lens spacing region LSR may extend further between the 2a lens 222(LS1) of the first lens group LSG1 and the 2a lens 222(LS1) of the second lens group LSG2. The lens spacing region LSR may extend further between the 2b lens 224(LS1) of the first lens group LSG1 and the 2b lens 224(LS1) of the second lens group LSG2. The lens spacing region LSR between the first lens group LSG1 and the second lens group LSG2 may contact the second lens LS2 between the 2a lens 222(LS1) of the first lens group LSG1 and the 2a lens 222(LS1) of the second lens group LSG2 and the second lens LS2 between the 2b lens 224(LS1) of the first lens group LSG1 and the 2b lens 224(LS1) of the second lens group LSG2.

The lens spacing region LSR between the third lens group LSG3 and the fourth lens group LSG4 may extend further between a pair of first lenses LS1 that are included in the third lens group LSG3 and the fourth lens group LSG4, respectively, and face along the first direction DR1. The lens spacing region LSR may extend further between the 2a lens 222(LS1) of the third lens group LSG3 and the 2a lens 222(LS1) of the fourth lens group LSG4. The lens spacing region LSR may extend further between the 2b lens 224(LS1) of the third lens group LSG3 and the 2b lens 224(LS1) of the fourth lens group LSG4. The lens spacing region LSR between the third lens group LSG3 and the fourth lens group LSG4 may contact the second lens LS2 between the 2a lens 222(LS1) of the third lens group LSG3 and the 2a lens 222(LS1) of the fourth lens group LSG4 and the second lens LS2 between the 2b lens 224(LS1) of the third lens group LSG3 and the 2b lens 224(LS1) of the fourth lens group LSG4. In example embodiments, from a planar perspective, the lens spacing region LSR between the first lens group LSG1 and the second lens group LSG2 and the lens spacing region LSR between the third lens group LSG3 and the fourth lens group LSG4 may have substantially the same area.

A pair of first lenses LS1 that are provided on each of a pair of first active regions AR1 immediately adjacent to each other along the second direction DR2 and face along the second direction DR2 may be spaced apart. The 2b lens 224(LS1) of the first lens group LSG1 and the 2a lens 222(LS1) of the third lens group LSG3 may be spaced apart. The 2b lens 224(LS1) of the second lens group LSG2 and the 2a lens 222(LS1) of the fourth lens group LSG4 may be spaced apart.

A lens spacing region LSR may be provided between the first lens group LSG1 and the third lens group LSG3. The lens spacing region LSR may extend between the 2b lens 224(LS1) of the first lens group LSG1 and the 2a lens 222(LS1) of the third lens group LSG3. The lens spacing region LSR between the first lens group LSG1 and the third lens group LSG3 may contact a pair of second lenses LS2 between the 2b lens 224(LS1) of the first lens group LSG1 and the 2a lens 222(LS1) of the third lens group LSG3.

A lens spacing region LSR may be provided between the second lens group LSG2 and the fourth lens group LSG4. The lens spacing region LSR may extend between the 2b lens 224(LS1) of the second lens group LSG2 and the 2a lens 222(LS1) of the fourth lens group LSG4. The lens spacing region LSR between the second lens group LSG2 and the fourth lens group LSG4 may contact a pair of second lenses LS2 between the 2b lens 224(LS1) of the second lens group LSG2 and the 2a lens 222(LS1) of the fourth lens group LSG4. In example embodiments, from a planar perspective, the lens spacing region LSR between the first lens group LSG1 and the third lens group LSG3 and the lens spacing region LSR between the second lens group LSG2 and the fourth lens group LSG4 may have substantially the same area.

From a planar perspective, the lens spacing region LSR between a pair of first lenses LS1 that are provided on each of a pair of first active regions AR1 immediately adjacent to each other along the first direction DR1 and face along the first direction DR1 may have a larger area than the lens spacing region LSR between a pair of first lenses LS1 that are provided on each of a pair of first active regions AR1 immediately adjacent to each other along the second direction DR2 and face along the second direction DR2. For example, from a planar perspective, the lens spacing region LSR between the first lens group LSG1 and the second lens group LSG2 and the lens spacing region LSR between the third lens group LSG3 and the fourth lens group LSG4 may have a larger area than the lens spacing region LSR between the first lens group LSG1 and the third lens group LSG3 and the lens spacing region LSR between the second lens group LSG2 and the fourth lens group LSG4.

From a planar perspective, each of the 2a lens 222(LS1) and the 2b lens 224(LS1) may have a shape that expands and then narrows as it gets farther from the boundary between the 2a lens 222(LS1) and the 2b lens 224(LS1). The width of the 2a lens 222(LS1) along the first direction DR1 may increase along the second direction DR2 between a pair of lens spacing regions LSR immediately adjacent to each other along the first direction DR1, and may decrease along the second direction DR2 between a pair of second lenses LS2 immediately adjacent to each other along the first direction DR1. The width of the 2b lens 224(LS1) along the first direction DR1 may increase along the opposite direction to the second direction DR2 between a pair of lens spacing regions LSR immediately adjacent to each other along the first direction DR1, and may decrease along the opposite direction to the second direction DR2 between a pair of second lenses LS2 immediately adjacent to each other along the first direction DR1.

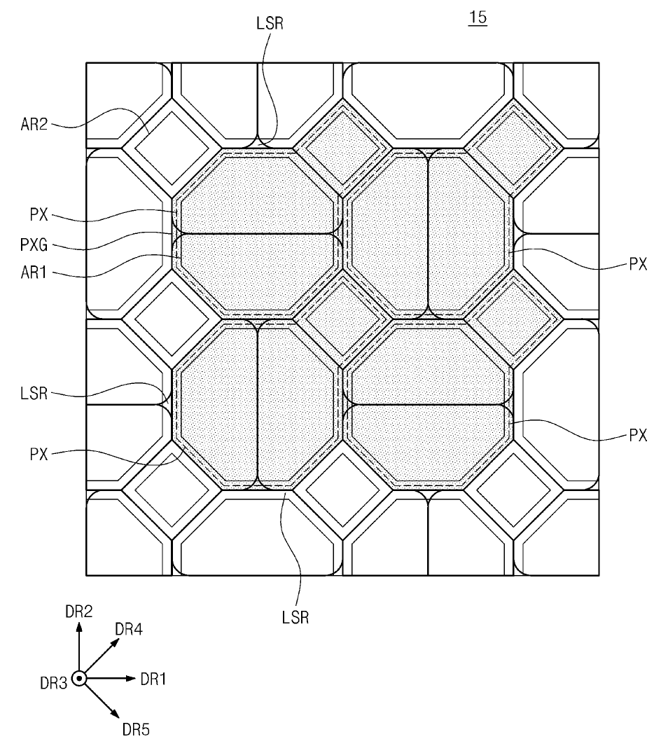

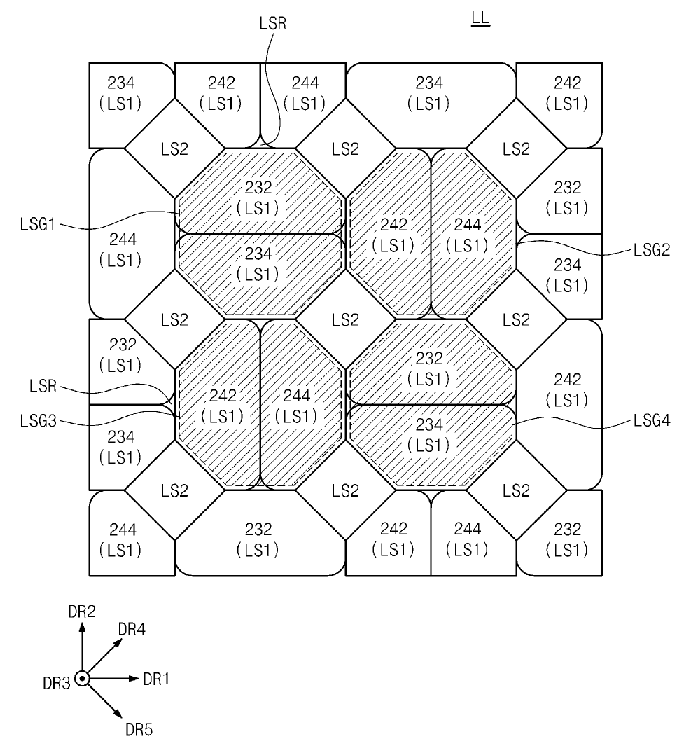

FIG. 21 is a plan view of an image sensor according to example embodiments. FIG. 22 is a plan view of the lens layer of FIG. 21. For conciseness, differences from what was described with reference to FIGS. 17 and 18 are explained.

Referring to FIGS. 21 and 22, image sensor 15 may be provided. Unlike what was described with reference to FIGS. 17 and 18, two first lenses LS1 arranged along the second direction DR2 or two first lenses LS1 arranged along the first direction DR1 may be provided on each of the first active regions AR1. The two first lenses LS1 arranged along the second direction DR2 and the two first lenses LS1 arranged along the first direction DR1 may be alternately arranged along the first direction DR1 and the second direction DR2.

For example, the first lens group LSG1 and the fourth lens group LSG4 may include two first lenses LS1 arranged along the second direction DR2. In each of the first lens group LSG1 and the fourth lens group LSG4, the two first lenses LS1 arranged along the second direction DR2 may be referred to as a 3a lens 232(LS1) and a 3b lens 234(LS1). For example, the second lens group LSG2 and the third lens group LSG3 may include two first lenses LS1 arranged along the first direction DR1. In each of the second lens group LSG2 and the third lens group LSG3, the two first lenses LS1 arranged along the first direction DR1 may be referred to as a 4a lens 242(LS1) and a 4b lens 244(LS1).

First lenses LS1 that are provided on each of a pair of first active regions AR1 immediately adjacent to each other along the first direction DR1 and face along the first direction DR1 may be connected. The 3a lens 232(LS1) and 3b lens 234(LS1) of the first lens group LSG1 may be connected to the 4a lens 242(LS1) of the second lens group LSG2. The 4b lens 244(LS1) of the third lens group LSG3 may be connected to the 3a lens 232(LS1) and 3b lens 234(LS1) of the fourth lens group LSG4.

The boundary between first lenses LS1 that are provided on each of a pair of first active regions AR1 immediately adjacent to each other along the first direction DR1 and face along the first direction DR1 may extend along the second direction DR2. The boundary between the 3a lens 232(LS1) of the first lens group LSG1 and the 4a lens 242(LS1) of the second lens group LSG2 and the boundary between the 3b lens 234(LS1) of the first lens group LSG1 and the 4a lens 242(LS1) of the second lens group LSG2 may extend along the second direction DR2. The boundary between the 4b lens 244(LS1) of the third lens group LSG3 and the 3a lens 232(LS1) of the fourth lens group LSG4 and the boundary between the 4b lens 244(LS1) of the third lens group LSG3 and the 3b lens 234(LS1) of the fourth lens group LSG4 may extend along the second direction DR2.

A lens spacing region LSR may be provided between the first lens group LSG1 and the second lens group LSG2. The lens spacing region LSR may be provided between the 3a lens 232(LS1) of the first lens group LSG1, the 3b lens 234(LS1) of the first lens group LSG1, and the 4a lens 242(LS1) of the second lens group LSG2. A lens spacing region LSR may be provided between the third lens group LSG3 and the fourth lens group LSG4. The lens spacing region LSR may be provided between the 4b lens 244(LS1) of the third lens group LSG3, the 3a lens 232(LS1) of the fourth lens group LSG4, and the 3b lens 234(LS1) of the fourth lens group LSG4.

First lenses LS1 that are provided on each of a pair of first active regions AR1 immediately adjacent to each other along the second direction DR2 and face along the second direction DR2 may be connected. The 3b lens 234(LS1) of the first lens group LSG1 may be connected to the 4a lens 242(LS1) and 4b lens 244(LS1) of the third lens group LSG3. The 4a lens 242(LS1) and 4b lens 244(LS1) of the second lens group LSG2 may be connected to the 3a lens 232(LS1) of the fourth lens group LSG4.

The boundary between first lenses LS1 that are provided on each of a pair of first active regions AR1 immediately adjacent to each other along the second direction DR2 and face along the second direction DR2 may extend along the first direction DR1. The boundary between the 3a lens 232(LS1) of the first lens group LSG1 and the 4a lens 242(LS1) of the third lens group LSG3 and the boundary between the 3b lens 234(LS1) of the first lens group LSG1 and the 4a lens 242(LS1) of the third lens group LSG3 may extend along the first direction DR1. The boundary between the 4a lens 242(LS1) of the second lens group LSG2 and the 3a lens 232(LS1) of the fourth lens group LSG4 and the boundary between the 4b lens 244(LS1) of the second lens group LSG2 and the 3a lens 232(LS1) of the fourth lens group LSG4 may extend along the first direction DR1.

A lens spacing region LSR may be provided between the first lens group LSG1 and the third lens group LSG3. The lens spacing region LSR may be provided between the 3b lens 234(LS1) of the first lens group LSG1, the 4a lens 242(LS1) of the third lens group LSG3, and the 4b lens 244(LS1) of the third lens group LSG3. A lens spacing region LSR may be provided between the second lens group LSG2 and the fourth lens group LSG4. The lens spacing region LSR may be provided between the 4a lens 242(LS1) of the second lens group LSG2, the 4b lens 244(LS1) of the second lens group LSG2, and the 3a lens 232(LS1) of the fourth lens group LSG4. In example embodiments, from a planar perspective, the lens spacing region LSR between the first lens group LSG1 and the second lens group LSG2, the lens spacing region LSR between the first lens group LSG1 and the third lens group LSG3, the lens spacing region LSR between the second lens group LSG2 and the fourth lens group LSG4, and the lens spacing region LSR between the third lens group LSG3 and the fourth lens group LSG4 may have substantially the same area.

One of two first lenses LS1 provided on each of the first active regions AR1 may be connected to the second lens LS2. The 3b lens 234(LS1) of the first lens group LSG1, the 4a lens 242(LS1) of the second lens group LSG2, the 4b lens 244(LS1) of the third lens group LSG3, and the 3a lens 232(LS1) of the fourth lens group LSG4 may be connected to the second lens LS2.

The 3b lens 234(LS1) of the first lens group LSG1, the second lens LS2, and the 3a lens 232(LS1) of the fourth lens group LSG4 may be sequentially connected along the fifth direction DR5. The boundary between the 3b lens 234(LS1) of the first lens group LSG1 and the second lens LS2 and the boundary between the 3a lens 232(LS1) of the fourth lens group LSG4 and the second lens LS2 may be substantially parallel to each other. The boundary between the 3b lens 234(LS1) of the first lens group LSG1 and the second lens LS2 and the boundary between the 3a lens 232(LS1) of the fourth lens group LSG4 and the second lens LS2 may extend along the fourth direction DR4.

The 4a lens 242(LS1) of the second lens group LSG2, the second lens LS2, and the 4b lens 244(LS1) of the third lens group LSG3 may be sequentially connected along the fourth direction DR4. The boundary between the 4a lens 242(LS1) of the second lens group LSG2 and the second lens LS2 and the boundary between the 4b lens 244(LS1) of the third lens group LSG3 and the second lens LS2 may be substantially parallel to each other. The boundary between the 4a lens 242(LS1) of the second lens group LSG2 and the second lens LS2 and the boundary between the 4b lens 244(LS1) of the third lens group LSG3 and the second lens LS2 may extend along the fifth direction DR5.

The remaining one of two first lenses LS1 provided on each of the first active regions AR1 may be spaced apart from the second lens LS2 located between the first to fourth lens groups LSG1 to LSG4. The 3a lens 232(LS1) of the first lens group LSG1, the 4b lens 244(LS1) of the second lens group LSG2, the 4a lens 242(LS1) of the third lens group LSG3, and the 3b lens 234(LS1) of the fourth lens group LSG4 may be spaced apart from the second lens LS2 located between the first to fourth lens groups LSG1 to LSG4.

The width of the 3a lens 232(LS1) along the first direction DR1 may increase along the second direction DR2 between a pair of lens spacing regions LSR immediately adjacent to each other along the first direction DR1, and may decrease along the second direction DR2 between a pair of second lenses LS2 immediately adjacent to each other along the first direction DR1. The width of the 3a lens 232(LS1) along the first direction DR1 may be constant between the lens spacing region LSR and the second lens LS2 immediately adjacent to each other along the second direction DR2.

The width of the 3b lens 234(LS1) along the first direction DR1 may increase along the second direction DR2 between a pair of second lenses LS2 immediately adjacent to each other along the first direction DR1, and may decrease along the second direction DR2 between a pair of lens spacing regions LSR immediately adjacent to each other along the first direction DR1. The width of the 3b lens 234(LS1) along the first direction DR1 may be constant between the lens spacing region LSR and the second lens LS2 immediately adjacent to each other along the second direction DR2.

The width of the 4a lens 242(LS1) along the second direction DR2 may increase along the first direction DR1 between a pair of second lenses LS2 immediately adjacent to each other along the second direction DR2, and may decrease along the first direction DR1 between a pair of lens spacing regions LSR immediately adjacent to each other along the second direction DR2. The width of the 4a lens 242(LS1) along the second direction DR2 may be constant between the lens spacing region LSR and the second lens LS2 immediately adjacent to each other along the first direction DR1.

The width of the 4b lens 244(LS1) along the second direction DR2 may increase along the first direction DR1 between a pair of lens spacing regions LSR immediately adjacent to each other along the second direction DR2, and may decrease along the first direction DR1 between a pair of second lenses LS2 immediately adjacent to each other along the second direction DR2. The width of the 4b lens 244(LS1) along the second direction DR2 may be constant between the lens spacing region LSR and the second lens LS2 immediately adjacent to each other along the first direction DR1.

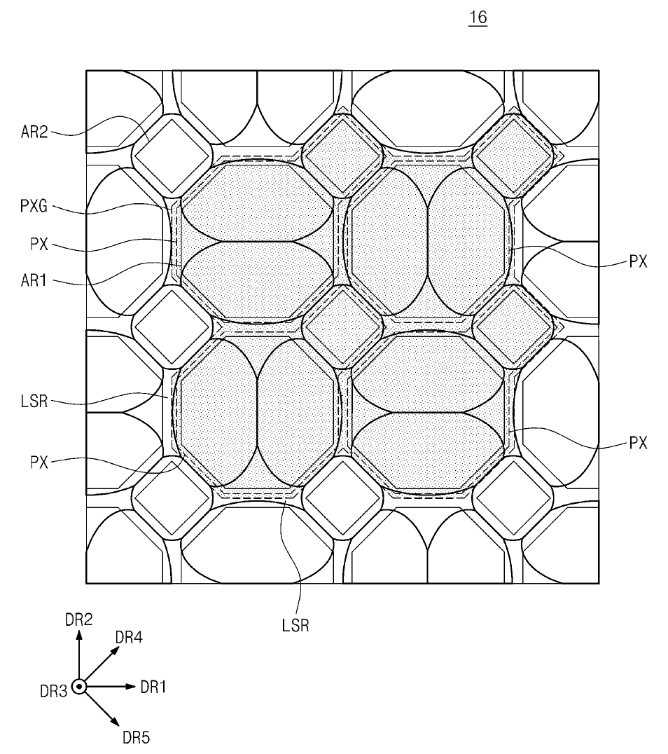

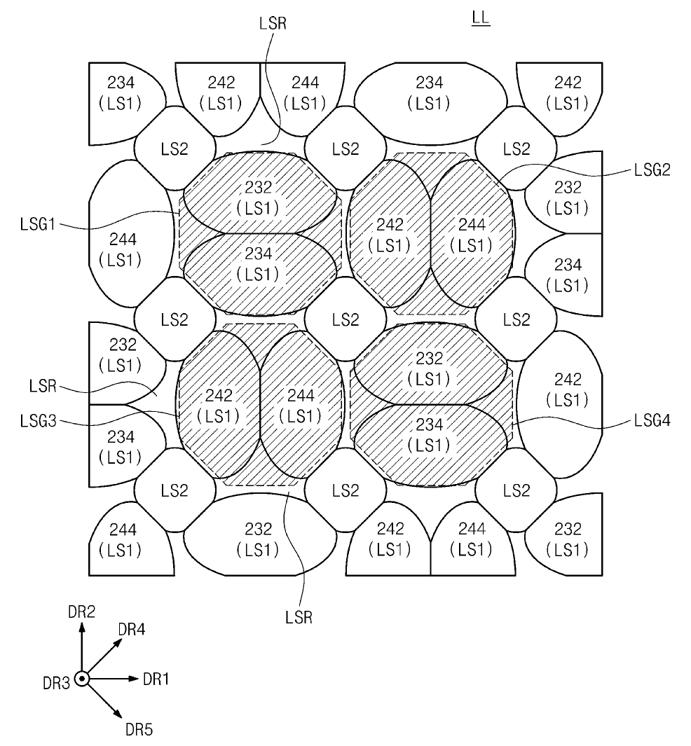

FIG. 23 is a plan view of an image sensor according to example embodiments. FIG. 24 is a plan view of the lens layer of FIG. 23. For conciseness, differences from what was described with reference to FIGS. 19 and 20 are explained.

Referring to FIGS. 23 and 24, image sensor 16 may be provided. Unlike what was described with reference to FIGS. 19 and 20, first lenses LS1 that are provided on each of a pair of first active regions AR1 immediately adjacent to each other along the first direction DR1 and face along the first direction DR1 may be spaced apart. The 3a lens 232(LS1) and 3b lens 234(LS1) of the first lens group LSG1 may be spaced apart from the 4a lens 242(LS1) of the second lens group LSG2. The 4b lens 244(LS1) of the third lens group LSG3 may be spaced apart from the 3a lens 232(LS1) and 3b lens 234(LS1) of the fourth lens group LSG4.

The lens spacing region LSR between the first lens group LSG1 and the second lens group LSG2 may extend further between first lenses LS1 that face along the first direction DR1 and are included in the first lens group LSG1 and the second lens group LSG2. The lens spacing region LSR may extend further between the 3a lens 232(LS1) of the first lens group LSG1 and the 4a lens 242(LS1) of the second lens group LSG2. The lens spacing region LSR may extend further between the 3b lens 234(LS1) of the first lens group LSG1 and the 4a lens 242(LS1) of the second lens group LSG2. The lens spacing region LSR between the first lens group LSG1 and the second lens group LSG2 may contact the second lens LS2 between the 3a lens 232(LS1) of the first lens group LSG1 and the 4a lens 242(LS1) of the second lens group LSG2 and the second lens LS2 between the 3b lens 234(LS1) of the first lens group LSG1 and the 4a lens 242(LS1) of the second lens group LSG2.

The lens spacing region LSR between the third lens group LSG3 and the fourth lens group LSG4 may extend further between first lenses LS1 that face along the first direction DR1. The first lenses LS1 are included in the third lens group LSG3 and the fourth lens group LSG4. The lens spacing region LSR may extend further between the 4b lens 244(LS1) of the third lens group LSG3 and the 3a lens 232(LS1) of the fourth lens group LSG4. The lens spacing region LSR may extend further between the 4b lens 244(LS1) of the third lens group LSG3 and the 3b lens 234(LS1) of the fourth lens group LSG4. The lens spacing region LSR between the third lens group LSG3 and the fourth lens group LSG4 may contact the second lens LS2 between the 4b lens 244(LS1) of the third lens group LSG3 and the 3a lens 232(LS1) of the fourth lens group LSG4 and the second lens LS2 between the 4b lens 244(LS1) of the third lens group LSG3 and the 3b lens 234(LS1) of the fourth lens group LSG4.

A pair of first lenses LS1 that are provided on each of a pair of first active regions AR1 immediately adjacent to each other along the second direction DR2 and face along the second direction DR2 may be spaced apart. The 3b lens 234(LS1) of the first lens group LSG1 may be spaced apart from the 4a lens 242(LS1) and 4b lens 244(LS1) of the third lens group LSG3. The 4a lens 242(LS1) and 4b lens 244(LS1) of the second lens group LSG2 may be spaced apart from the 3a lens 232(LS1) of the fourth lens group LSG4.

The lens spacing region LSR between the first lens group LSG1 and the third lens group LSG3 may be provided between the first lens group LSG1 and the third lens group LSG3 and may extend between the 3b lens 234(LS1) of the first lens group LSG1 and the 4a lens 242(LS1) of the third lens group LSG3. The lens spacing region LSR between the first lens group LSG1 and the third lens group LSG3 may contact a pair of second lenses LS2 between the 3b lens 234(LS1) of the first lens group LSG1 and the 4a lens 242(LS1) of the third lens group LSG3.

A lens spacing region LSR may be provided between the second lens group LSG2 and the fourth lens group LSG4. The lens spacing region LSR may extend between the 2b lens 224(LS1) of the second lens group LSG2 and the 3a lens 232(LS1) of the fourth lens group LSG4. The lens spacing region LSR between the second lens group LSG2 and the fourth lens group LSG4 may contact a pair of second lenses LS2 between the 2b lens 224(LS1) of the second lens group LSG2 and the 3a lens 232(LS1) of the fourth lens group LSG4. In example embodiments, from a planar perspective, the lens spacing region LSR between the first lens group LSG1 and the third lens group LSG3 and the lens spacing region LSR between the second lens group LSG2 and the fourth lens group LSG4 may have substantially the same area.

From a planar perspective, each of the 3a lens 232(LS1) and the 3b lens 234(LS1) may have a shape that expands and then narrows as it gets farther from the boundary between the 3a lens 232(LS1) and the 3b lens 234(LS1). The width of the 3a lens 232(LS1) along the first direction DR1 may increase along the second direction DR2 between a pair of lens spacing regions LSR immediately adjacent to each other along the first direction DR1, and may decrease along the second direction DR2 between a pair of second lenses LS2 immediately adjacent to each other along the first direction DR1. The width of the 3b lens 234(LS1) along the first direction DR1 may increase along the opposite direction to the second direction DR2 between a pair of lens spacing regions LSR immediately adjacent to each other along the first direction DR1, and may decrease along the opposite direction to the second direction DR2 between a pair of second lenses LS2 immediately adjacent to each other along the first direction DR1.

From a planar perspective, each of the 4a lens 242(LS1) and the 4b lens 244(LS1) may have a shape that expands and then narrows as it gets farther from the boundary between the 4a lens 242(LS1) and the 4b lens 244(LS1). The width of the 4a lens 242(LS1) along the second direction DR2 may increase along the opposite direction to the first direction DR1 between a pair of lens spacing regions LSR immediately adjacent to each other along the second direction DR2, and may decrease along the opposite direction to the first direction DR1 between a pair of second lenses LS2 immediately adjacent to each other along the second direction DR2. The width of the 4b lens 244(LS1) along the second direction DR2 may increase along the first direction DR1 between a pair of lens spacing regions LSR immediately adjacent to each other along the second direction DR2, and may decrease along the first direction DR1 between a pair of second lenses LS2 immediately adjacent to each other along the second direction DR2.

According to the present disclosure, an image sensor having improved optical characteristics and improved manufacturing process efficiency may be provided.

According to the present disclosure, a method for manufacturing an image sensor having improved optical characteristics and improved manufacturing process efficiency may be provided.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. An image sensor comprising:
a first active region comprising a first photoelectric conversion region;
a second active region comprising a second photoelectric conversion region, wherein the second active region has a smaller area than the first active region;
a plurality of first lenses on the first active region; and
a second lens on the second active region,
wherein the second lens is connected to one of the plurality of first lenses and spaced apart from the other first lenses.

2. The image sensor of claim 1, wherein the plurality of first lenses are arranged along a first direction and a second direction,
wherein the second lens and a first lens are connected along a fourth direction intersecting the first direction and the second direction, and
wherein the first lens is immediately adjacent to the second lens.

3. The image sensor of claim 2, further comprising a lens spacing region that is between a pair of first lenses among the plurality of first lenses,
wherein the pair of first lenses are arranged along the fourth direction.

4. The image sensor of claim 2, wherein a pair of first lenses, among the plurality of first lenses, are connected and arranged along the fourth direction.

5. The image sensor of claim 2, wherein the plurality of first lenses are arranged in a 2×2 form along the first direction and the second direction.

6. The image sensor of claim 1, wherein the plurality of first lenses are arranged along a first direction or a second direction,
wherein the second lens and a first lens among the plurality of first lenses are connected along a fourth direction intersecting the first direction and the second direction, and
wherein the first lens is immediately adjacent to the second lens.

7. An image sensor comprising:
first active regions arranged in a 2×2 form along a first direction and a second direction, wherein each of the first active regions comprises first photoelectric conversion regions;
a second active region provided between the first active regions, wherein the second active region comprises a second photoelectric conversion region and the second active region has a smaller area than each of the first active regions;
a first lens group, a second lens group, a third lens group, and a fourth lens group that are provided on respective first active regions and, wherein each of the first lens group, the second lens group, the third lens group, and the fourth lens group comprises a plurality of first lenses; and
a second lens provided between the first lens group, the second lens group, the third lens group, and the fourth lens group,
wherein the second lens is connected to one of the plurality of first lenses in each of the first lens group, the second lens group, the third lens grp, and the fourth lens group, and
wherein the second lens is spaced apart from the other first lenses.

8. The image sensor of claim 7, wherein the first lens group and the second lens group are arranged along the first direction, and
wherein, among the first lenses in the first lens group and the second lens group, a pair of first lenses, which are immediately adjacent to each other along the first direction and respectively included in the first lens group and the second lens group, are connected along the first direction.

9. The image sensor of claim 8, further comprising a lens spacing region that is between the first lens group and the second lens group,
wherein the lens spacing region is spaced apart from the second lens.

10. The image sensor of claim 7, wherein the third lens group and the first lens group are arranged along the second direction, and
wherein, among the first lenses in the third lens group and the first lens group, a pair of first lenses, which are immediately adjacent to each other along the second direction and respectively included in the third lens group and the first lens group, are connected along the second direction.

11. The image sensor of claim 7, wherein the first lens group and the second lens group are arranged along the first direction, and
wherein, among the first lenses in the first lens group and the second lens group, a pair of first lenses, which are immediately adjacent to each other along the first direction and respectively included in the first lens group and the second lens group, are spaced apart along the first direction.

12. The image sensor of claim 11, further comprising a lens spacing region that is between the first lens group and the second lens group,
wherein the lens spacing region contacts the second lens.

13. The image sensor of claim 11, wherein the third lens group and the first lens group are arranged along the second direction, and
wherein, among the first lenses included in the third lens group and the first lens group, a pair of first lenses, which are immediately adjacent to each other along the second direction and respectively included in the third lens group and the first lens group, are spaced apart along the second direction.

14. The image sensor of claim 7, wherein each of the first lens group, the second lens group, the third lens group, and the fourth lens group comprises four first lenses arranged in a 2×2 form along the first direction and the second direction.

15. The image sensor of claim 7, wherein each of the first lens group, the second lens group, the third lens group, and the fourth lens group comprises two first lenses arranged along the first direction or the second direction.

16. The image sensor of claim 15, wherein a first set of two first lenses arranged along the first direction and a second set of two first lenses arranged along the second direction are alternately arranged along the first direction and the second direction.

17. An image sensor comprising:
a first active region comprising a first photoelectric conversion region;
a plurality of second active regions arranged along an edge of the fist active region, wherein each of the plurality of second active regions comprises a plurality of second photoelectric conversion regions;
a plurality of first lenses on the first active region;
a plurality of second lenses on the plurality of second active regions, respectively;
wherein the plurality of second lenses are connected to one of the plurality of first lenses, and
wherein the plurality of second lenses are spaced apart from the other first lenses.

18. The image sensor of claim 17, wherein the plurality of first lenses are in contact with the plurality of second lenses, respectively.

19. The image sensor of claim 18, wherein the plurality of first lenses are arranged in a 2×2 form along a first direction and a second direction,
wherein the plurality of second lenses are arranged in a 2×2 form along the first direction and the second direction.

20. The image sensor of claim 17, wherein each of the plurality of first lenses is in contact with at least two of the plurality of second lenses.
